(19) United States
(12) Patent Application Publication
(10) Pub. No.: US 2016/0118126 A1
(43) Pub. Date: Apr. 28, 2016

(54) NONVOLATILE MEMORY DEVICES AND PROGRAM METHOD THEREOF

(71) Applicants: Sungsu Moon, Hwaseong-si (KR); Changsub LEE, Hwaseong-si (KR); Raeyoung LEE, Seongnam-si (KR); Soyeong GWAK, Bupyeong-gu (KR)

(72) Inventors: Sungsu Moon, Hwaseong-si (KR); Changsub LEE, Hwaseong-si (KR); Raeyoung LEE, Seongnam-si (KR); Soyeong GWAK, Bupyeong-gu (KR)

(21) Appl. No.: 14/854,097

(22) Filed: Sep. 15, 2015

(30) Foreign Application Priority Data
Oct. 22, 2014 (KR) 10-2014-0143583

(51) Int. Cl. G11C 16/12; G11C 16/34; G06F 12/02

(52) U.S. Cl. CPC G11C 16/12; G06F 12/0246; G11C 16/3431; G06F 2212/7208

(57) ABSTRACT

A program method of a nonvolatile memory device is provided which includes programming memory cells to a target state using a verification voltage and an incremental step pulse, selecting memory cells, each having a threshold voltage lower than a supplementary verification voltage, from among the memory cells programmed to the target state, and applying a supplementary program voltage to the selected memory cells. The supplementary verification voltage is equal to or higher than the verification voltage, and the supplementary program voltage is equal to or lower than a program voltage provided in a program loop where a programming of the memory cells to the target state is completed.

### CROSS-REFERENCE TO RELATED APPLICATIONS

A claim for priority under 35 U.S.C. §119 is made to Korean Patent Application No. 10-2014-0143583 filed Oct. 22, 2014, in the Korean Intellectual Property Office, the entire contents of which are hereby incorporated by reference.

### BACKGROUND

Semiconductor memory devices may be volatile or nonvolatile. The volatile semiconductor memory devices may perform read and write operations at high speed; contents stored therein may be lost at power-off. The nonvolatile semiconductor memory devices may retain contents stored therein. The nonvolatile semiconductor memory devices may be used to store contents which may be retained regardless of whether or not they are powered.

A flash memory device may be a typical nonvolatile semiconductor memory device. The flash memory device may be widely used as a voice and image data storing medium of information appliances, such as a computer, a cellular phone, a PDA, a digital camera, a camcorder, a voice recorder, an MP3 player, a handheld PC, a game machine, a facsimile, a scanner, a printer, and the like.

As a demand on a mass storage device increases, a multi-level cell (MLC) or multi-bit memory device is widely used which stores multiple bits per cell. However, in a memory device employing multi-level cells, threshold voltages of memory cells may be identified as a plurality of states within a restricted voltage window. Threshold voltages of memory cells vary with a characteristic of the memory device or the lapse of time and a peripheral temperature. Hence, a variety of methods for identifying data states are used to improve data integrity. Among the methods, one is to prevent the drooping and spreading of threshold voltage distributions corresponding to program states. That is, such a method is to reduce the drooping and spreading of threshold voltage distributions corresponding to pieces of different data. However, the method necessitates a program time additionally, thereby lowering performance.

### SUMMARY

Embodiments of the inventive concepts provide nonvolatile memory devices and programming methods thereof capable of minimizing lowering of performance of the nonvolatile memory devices, thereby making threshold voltage distributions of memory cells better.

One aspect of embodiments of the inventive concept is directed to provide program methods of a nonvolatile memory device which include programming memory cells to a target state using a verification voltage and incremental step pulses, selecting memory cells, each having a threshold voltage lower than a supplementary verification voltage, from among the memory cells programmed to the target state, and applying a supplementary program voltage to the selected memory cells, wherein the supplementary verification voltage is equal to or higher than the verification voltage and the supplementary program voltage is equal to or lower than a program voltage, provided in a program loop where a programming of the memory cells to the target state is completed, from among the incremental step pulses.

Another aspect of embodiments of the inventive concept is directed to provide nonvolatile memory devices which include a cell array, a page buffer, a voltage generator, and control logic. The cell array includes a plurality of memory cells. The page buffer is connected to the cell array through bit lines and transfers data to be written at selected memory cells to the bit lines. The voltage generator provides an incremental program pulse and a verification voltage to a word line connected with the selected memory cells at a normal program operation and provides a supplementary verification voltage and a supplementary program voltage to the word line at a supplementary program operation. The control logic controls the page buffer and the voltage generator to write the data at the selected memory cells depending on the normal program operation and the supplementary program operation. During the normal program operation, the page buffer provides the control logic with pass loop count information corresponding to each of target states to which the plurality of memory cells is programmed. Based on the pass loop count information, the control logic determines a supplementary verification voltage and a supplementary program voltage that are associated with at least one of the target states.

Still another aspect of embodiments of the inventive concept is directed to provide program methods of a nonvolatile memory device which include performing a normal program operation where memory cells are programmed to a target state using incremental step pulses, and performing a supplementary program operation where memory cells, each having a threshold voltage lower than a supplementary verification voltage, from among the memory cells are selected and a supplementary program voltage is applied to the selected memory cells, wherein the supplementary program voltage is higher than or equal to a verification voltage used at the normal program operation, and wherein the supplementary program voltage is lower than or equal to a program voltage that is used in a program loop where the target state is program passed at the normal program operation.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a block diagram schematically illustrating a nonvolatile memory device according to some embodiments of the inventive concept;

FIG. 2 is a perspective view of a memory block BLK included in a cell array shown in FIG. 1;

FIG. 3 is a cross-sectional view of a memory cell included in a memory block shown in FIG. 2;

FIG. 4 is a distribution diagram schematically illustrating drooping and spreading of a threshold voltage distribution of memory cells;

FIG. 5 is a flow chart schematically illustrating program methods of nonvolatile memory devices according to some embodiments of the inventive concept;

FIG. 6 is a diagram for describing effects according to some embodiments of the inventive concept;

FIG. 7 is a waveform diagram showing voltages applied to a word line of memory cells to be programmed to target states shown in FIG. 6;

FIGS. 8A and 8B are diagrams showing a supplementary program operation about 2-bit multi-level cells, according to some embodiments of the inventive concept;

FIGS. 9A and 9B are diagrams showing a supplementary program operation about 2-bit multi-level cells, according to some embodiments of the inventive concept;

FIG. 10 is a diagram showing methods of selecting memory cells to which a supplementary program operation according to some embodiments of the inventive concept is applied;

FIG. 11 is a diagram for describing how threshold voltage distributions of 3-bit multi-level cells are improved through a supplementary program operation;

FIG. 12 is a waveform diagram showing program voltages to be applied to memory cells having target states shown in FIG. 11;

FIGS. 13A and 13B are diagrams showing some embodiments in which a supplementary program operation is applied to a part of target states of 3-bit multi-level cells;

FIGS. 14A and 14B are diagrams showing some embodiments in which a supplementary program operation is applied to a part of target states of 3-bit multi-level cells;

FIG. 15 is a table showing a supplementary program table 155 shown in FIG. 1, according to some embodiments of the inventive concept;

FIG. 16 is a flow chart showing a program operation according to some embodiments of the inventive concept;

FIGS. 17A and 17B are timing diagrams showing some embodiments in which the number of supplementary program operations associated with each target state is changed;

FIG, 18 is a diagram schematically illustrating an effect according to embodiments of the inventive concept;

FIG. 19 is a block diagram schematically illustrating a solid state drive according to some embodiments of the inventive concept;

FIG. 20 is a block diagram schematically illustrating an eMMC according to some embodiments of the inventive concept;

FIG. 21 is a block diagram schematically illustrating a UFS system according to some embodiments of the inventive concept; and

FIG. 22 is a block diagram schematically illustrating a computing system according to some embodiments of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

In an embodiment of the present inventive concept, a three dimensional (3D) memory array is provided. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

In an embodiment of the present inventive concept, the 3D memory array includes vertical NAND strings that are vertically oriented such that at least one memory cell is located over another memory cell. The at least one memory cell may comprise a charge trap layer. Each vertical NAND string may include at least one select transistor located over memory cells, the at least one select transistor having the same structure with the memory cells and being formed monolithically together with the memory cells.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of devices may be arranged in an array and/or in a two-dimensional pattern.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

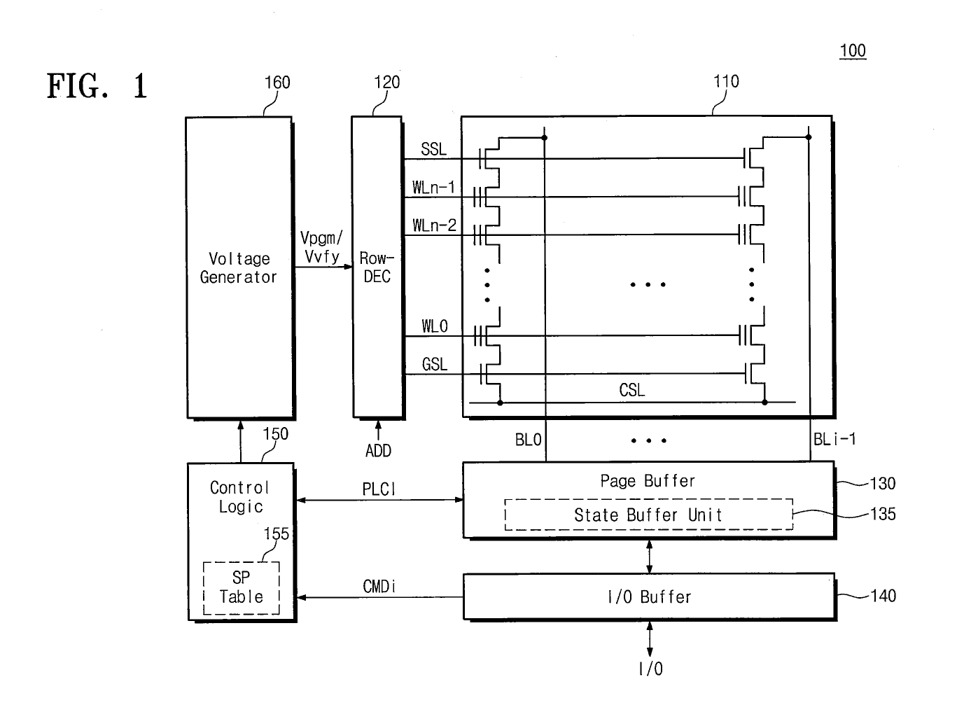

FIG. 1 is a block diagram schematically illustrating a nonvolatile memory device according to some embodiments of the inventive concept. Referring to FIG. 1, a nonvolatile memory device 100 contains a cell array 110, a row decoder 120, a page buffer 130, an input/output buffer 140, control logic 150, and a voltage generator 160.

The cell array 110 is connected to the row decoder 120 through word lines WL0 to WLn-1 and selection lines SSL and GSL. The cell array 110 is connected to the page buffer 130 through bit lines BL0 to BLi-1. The cell array 110 includes a plurality of cell strings (e.g., NAND cell strings). The cell strings may constitute a memory block BLK. In some example embodiments, a channel of each cell string may be formed in a vertical or horizontal direction.

At a program operation, memory cells may be selected by a predetermined unit (e.g., 2 KB (page) or 512 B) by controlling the word lines WL0 to WLn-1 and the selection lines SSL and GSL. At a read operation, memory cells may be selected by a predetermined unit (e.g., page or less). Threshold voltage distributions of memory cells may start to vary due to various causes from a point in time the program operation is completed. A threshold voltage variation reduces read margin, thereby lowering integrity of data. Program methods according to some embodiments of the inventive concept make a threshold voltage distribution better, thereby minimizing a decrease in performance and improving integrity of data. This will be more fully described together with describing functions of the page buffer 130 and the control logic 150.

The row decoder 120 selects one of memory blocks of the cell array 110 in response to an address ADD. The row decoder 120 selects one of the word lines WL0 to WLn-1 of the selected memory block. The row decoder 120 transfers a program voltage Vpgm or a verification voltage Vvfy from the voltage generator 126 to the selected word line. During a program operation, the row decoder 120 transfers a program/verification voltage Vpgm/Vvfy to a selected word line and a pass voltage Vpass to unselected word lines. During a read operation, the row decoder 120 transfers a selection read voltage Vrd to a selected word line and a non-selection read voltage Vread to unselected word lines.

The page buffer 130 acts as a write driver at a program operation and as a sense amplifier at a read operation. The page buffer 130 transfers bit line voltages corresponding to pieces of program data to bit lines of the cell array 110 at a program operation. At a read operation, the page buffer 130 senses data stored in a selected memory cell through a bit line. The page buffer 130 latches the sensed data and transfers it to the input/output buffer 140.

Upon programming memory cells, a program voltage is provided to a word line, based on an incremental step pulse programming (ISPP) manner. During the ISPP-based program operation, the applying of a program pulse and the applying of verification pulses are performed in a program loop. Selected memory cells are programmed to target states using a plurality of program loops. Even though the selected memory cells are programmed to the target states, the page buffer 130 according to some embodiments of the inventive concept maintains the program data without initialization. That is, the page buffer 130 stores data corresponding to the target states at an internal latch or a separate storage element. For this purpose, the page buffer 130 contains a state buffer unit 135.

During the program operation, the page buffer 130 provides the control logic 150 with pass loop count information PLCI corresponding to a point in time when the programming of the selected memory cells to the target states is passed. For example, the page buffer 130 provides the control logic 130 with a loop count at which the programming of memory cells, which will be programmed to a target state P1, from among selected memory cells is completed. When a loop count at which the programming of memory cells to be programmed to the target state P1 is completed is L4, the page buffer 130 provides the control logic 150 with the pass loop count information PLCI.

During a normal program operation, selected memory cells are programmed in the ISPP manner under a control of the control logic 150. After the normal program operation is completed, a supplementary program operation is executed according to a control of the control logic 150. For the supplementary program operation, the page buffer 130 uses program data stored at the state buffer unit 135. That is, specific memory cells are selected after the normal program operation ends and then are additionally programmed. The supplementary program operation makes it possible to increase threshold voltages of memory cells which have relatively low threshold voltages at the target states.

In some example embodiments, the state buffer unit 135 may be implemented with a separate storage element formed in the page buffer 130, such as, for example, a latch. In some embodiments, the state buffer unit 135 may be implemented with reserved latches of the page buffer 130 without separate storage elements.

The input/output buffer 140 provides write data received at a program operation to the page buffer 130. At a read operation, the input/output buffer 140 outputs read data provided from the page buffer 130 to an external device. The input/output buffer 140 provides input addresses or commands CMDi to the row decoder 120 and/or the control logic 150.

The control logic 150 controls the page buffer 130 and the row decoder 120 in response to a command CMDi from the external device. The control logic 150 controls the page buffer 130 and the voltage generator 160 in response to a program command such that data loaded on the page buffer 130 is programmed at selected memory cells. The control logic 150 selects a voltage needed for the supplementary program operation in response to the pass loop count information PLCI from the page buffer 130 at the normal program operation. The control logic 150 controls the page buffer 130 and the voltage generator 160 such that the supplementary program operation about selected memory cells is performed using selected supplementary program voltage and supplementary verification voltage. The control logic 150 configures a supplementary program table 155 for selecting the supplementary program voltage and the supplementary verification voltage referring to the pass loop count information PLCI. The supplementary program table 155 may be implemented with a fuse box or a variety of nonvolatile memory media (or, elements).

The voltage generator 160 generates word line voltages to be supplied to word lines and a voltage to be supplied to a bulk (e.g., a well area), at which memory cells are formed, according to a control of the control logic 150. The word line voltages to be applied to the word lines may include the following: a program voltage, a pass voltage Vpgm, a pass voltage Vpass, selection and non-selection read voltages. At a read and a program operation, the voltage generator 160 generates selection line voltages VSSL and VGSL that are supplied to the selection lines SSL and GSL.

Also, the voltage generator 160 generates a supplementary program voltage Vpgm_S1 and a supplementary verification voltage Vvfy_S1 that are provided to a word line of memory cells at the supplementary program operation. It is assumed that pass loop count information PLCI about memory cells to be programmed to a target state P2 corresponds to a loop count L8. For the supplementary program operation about the memory cells to be programmed to the target state P2, the voltage generator 160 generates a level of a supplementary verification voltage Vvfy_S2 that is equal to or higher than that of a verification voltage Vvfy2 corresponding to the target state P2. For the supplementary program operation about the memory cells to be programmed to the target state P2, the voltage generator 160 produces a supplementary program voltage Vpgm_S8 of which the level is equal to or lower than that of a program voltage Vpgm 8 to be provided at a program operation of the loop count L8.

The nonvolatile memory device 100 according to some embodiments of the inventive concept improves a threshold voltage distribution using the supplementary program operation, with a decrease in a program speed minimized. That is, memory cells, having threshold voltages lower than a specific voltage, from among program-completed memory cells are selectively programmed. Threshold voltages of memory cells programmed through the supplementary program operation do not exceed the upper limit of a threshold voltage distribution corresponding to a target state.

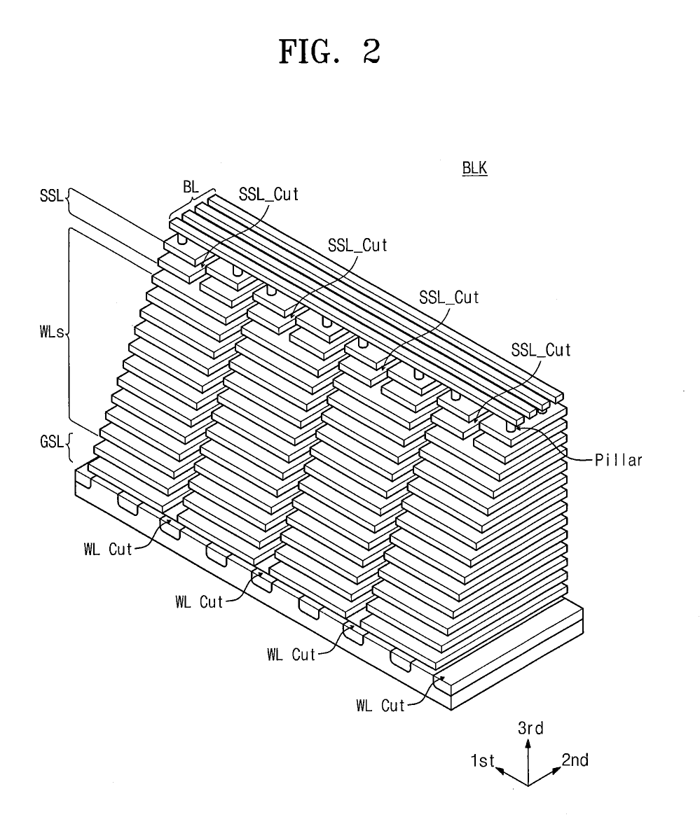

FIG. 2 is a perspective view of a memory block BLK included in a cell array shown in FIG. 1. Referring to FIG. 2, a memory block BLK includes four sub blocks that are formed on a substrate. The sub blocks are formed by stacking and cutting at least one ground selection line GSL, a plurality of word lines, and at least one string selection line SSL on the substrate in a plate shape. However, the scope and spirit of the inventive concept may not be limited thereto. The block BLK may be implemented to have a structure where a plurality of string selection lines are formed without a string cut SSL_Cut.

In some example embodiments, at least one plate-shaped dummy word line may be formed between the ground selection line GSL and the word lines. Some embodiments provide that at least one plate-shaped dummy word line may be formed between the word lines and the string selection line SSL. Each word line cut, although not shown in FIG. 2, may include a common source line CSL. In some example embodiments, the common source lines CSL included in the word line cuts may be interconnected. A string may be formed by making a pillar connected to a bit line penetrate the at least one string selection line SSL, the word lines, and the at least one ground selection line GSL.

In FIG. 2, some embodiments of the inventive concept are exemplified as a structure between adjacent word line cuts that is a sub block. However, the scope and spirit of the inventive concept may not be limited thereto. For example, a structure between a word line cut and a string selection line cut may be defined as a sub block.

The memory block BLK according to some embodiments of the inventive concept may be implemented to have a merged word line structure where two word lines are merged to one.

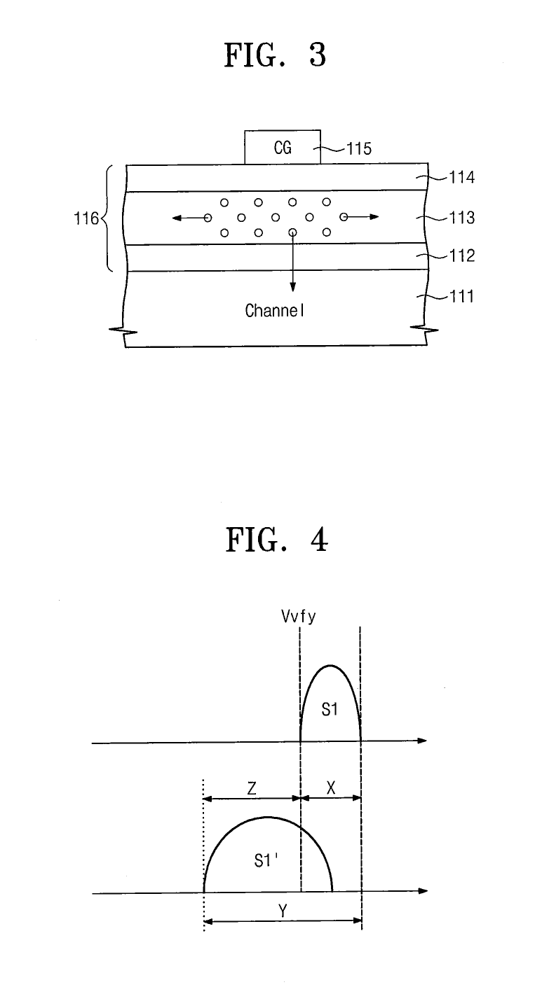

FIG. 3 is a cross-sectional view of a memory cell included in a memory block shown in FIG. 2. Referring to FIG. 3, a charge trap flash cell (hereinafter referred to as “CTF cell”) contains an information storage layer 116 for storing information. The information storage layer 116 includes a first oxide layer 112, a nitride layer 113 as a charge trap layer, and a second oxide layer 114 that are sequentially stacked on a channel 111. To program the CTF cell, a program voltage is applied to its control gate 115, and a predetermined voltage (e.g., 0 V) is applied to its channel. With this bias condition, an electric field may be formed in a direction from the control gate 115 to the channel 111. At this time, charge may move from the channel 111 to the charge trap layer 113. This may mean that the CTF cell is programmed under the bias condition.

To erase the CTF cell, a predetermined voltage (e.g., a voltage equal to or greater than 0 V) is applied to the control gate 115, and an erase voltage (e.g., 20 V) is applied to the channel 111. The CTF cell is erased because an electric field is formed in a direction from a bulk to the control gate 115 under to this bias condition.

In FIG. 3, locations of charges trapped in the charge trap layer 113 through programming may be illustrated for non-limiting examples. It is understood that locations of trapped charges may vary with a characteristic of a CTF cell. Some embodiments provide that charge trapped in the charge trap layer 113 through programming may decrease due to redistribution with time, discharge into the channel 111 (refer to an arrow marked in a vertical direction), and migration through the nitride layer 113 (refer to an arrow marked in a horizontal direction). This phenomenon may be referred to as “fast charge loss phenomenon”. A threshold voltage of a CTF cell may decrease due to the fast charge loss phenomenon. In addition, the fast charge loss phenomenon may cause the drooping and spreading of a threshold voltage distribution of CTF cells.

The drooping and spreading of the threshold voltage distribution of CTF cells may occur in various shapes or states with time. The longer a lapse time from a programmed point in time, the more the drooping and spreading of a threshold voltage distribution of CTF cells increases. In some example embodiments, it is possible to solve degradation of a threshold voltage distribution due to a slow charge loss phenomenon as well as the fast charge loss phenomenon.

FIG. 4 is a distribution diagram schematically illustrating drooping and spreading of a threshold voltage distribution of memory cells. Referring to FIG. 4, a threshold voltage distribution S1 of memory cells immediately after programming may be changed into a threshold voltage distribution S1′ with time.

Threshold voltages of programmed CTF cells may form a threshold voltage distribution S1 immediately after a program operation is carried out. The threshold voltages of the programmed CTF cells form a threshold voltage distribution S1′ after a program operation is performed and then a specific time elapses. In FIG. 4, a variation in the lower limit of a threshold voltage distribution, that is, the magnitude of Z may correspond to the drooping of the threshold voltage distribution S1′, and an expanded magnitude (Y−X) of the threshold voltage distribution S1′ may correspond to the spreading of the threshold voltage distribution S1′.

The drooping and spreading of the distribution may vary with time. As a time elapses, the drooping and spreading may enable threshold voltage distributions to overlap. A supplementary program operation according to some embodiments of the inventive concept makes it possible to supplement threshold voltages of memory cells that are placed at a lower side of a target state due to the drooping and spreading of a threshold voltage distribution or a program speed difference.

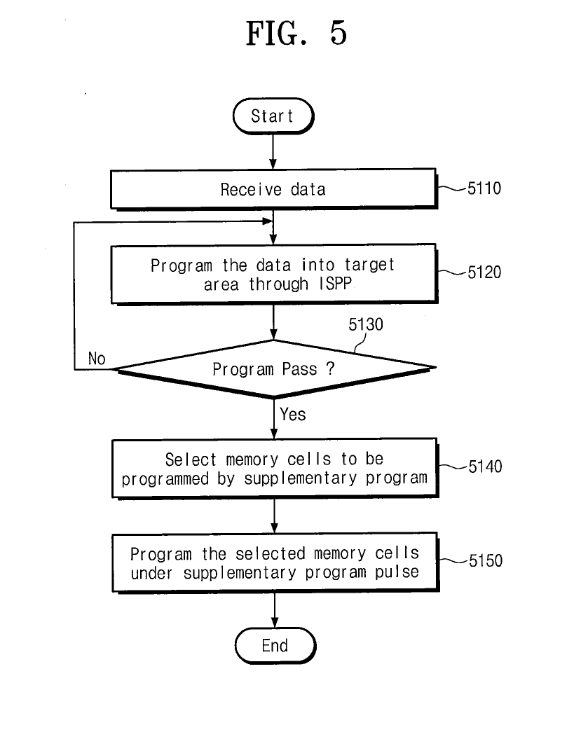

FIG. 5 is a flow chart schematically illustrating program methods of a nonvolatile memory device 100 according to some embodiments of the inventive concept. Referring to FIG. 5, a nonvolatile memory device 100 programs data, which is provided from an external device at a program operation, at a selected memory area, based on a normal program operation and a supplementary program operation.

In operation 5110, the nonvolatile memory device 100 receives a program command and data from the external device. It is, of course, understood that an address is provided with the program command. The data is loaded on a page buffer 130 shown in FIG. 1, and the program command is provided to control logic 150 shown in FIG. 5.

In operation 5120, the nonvolatile memory device 100 performs a normal program operation using an ISPP manner. That is, the nonvolatile memory device 100 applies a program voltage pulse that stepwise increases over the normal program operation. A plurality of verification voltages associated with a plurality of target states may be provided in every program loop to program multi-level cells. Pass loop count information PLCI associated with each target state may be provided to the control logic 150.

In operation 5130, the nonvolatile memory device 100 determines whether programming of the selected memory cells is completed. For example, the nonvolatile memory device 100 performs a verification operation about each target state. When a verification result about all target states indicates program pass, the normal program operation of the nonvolatile memory device 100 is determined as being completed. On this occasion, the method proceeds to operation 5140 to perform a supplementary program operation. In contrast, when memory cells exist which have threshold voltages lower than a verification voltage, the normal program operation of the nonvolatile memory device 100 is determined as being not completed. On this occasion, the method proceeds to operation 5120.

In operation 5140, the nonvolatile memory device 100 selects memory cells that necessitate the supplementary program operation. For example, the nonvolatile memory device 100 selects memory cells, corresponding to a specific target state, from among memory cells selected for programming. Memory cells, having threshold voltages lower than a reference value, from among memory cells corresponding to the selected target state are selected for the supplementary program operation. A supplementary verification voltage Vvfy_S1 is used to select memory cells to which the supplementary program operation is applied.

In operation 5150, the nonvolatile memory device 100 applies a supplementary program voltage to the memory cells selected for the supplementary program operation to perform the supplementary program operation. To program selected memory cells, the nonvolatile memory device 100 provides a program voltage that is equal to or lower than a program voltage corresponding to a pass loop count provided at the normal program operation. Threshold voltages of memory cells increase through the supplementary program operation and are lower than the upper limit defined.

As described above, the nonvolatile memory device 100 according to some embodiments of the inventive concept executes the supplementary program operation after the normal program operation is completed. Thus, it is possible to minimize an increase in a time taken to perform a program operation and to make a threshold voltage distribution of memory cells better.

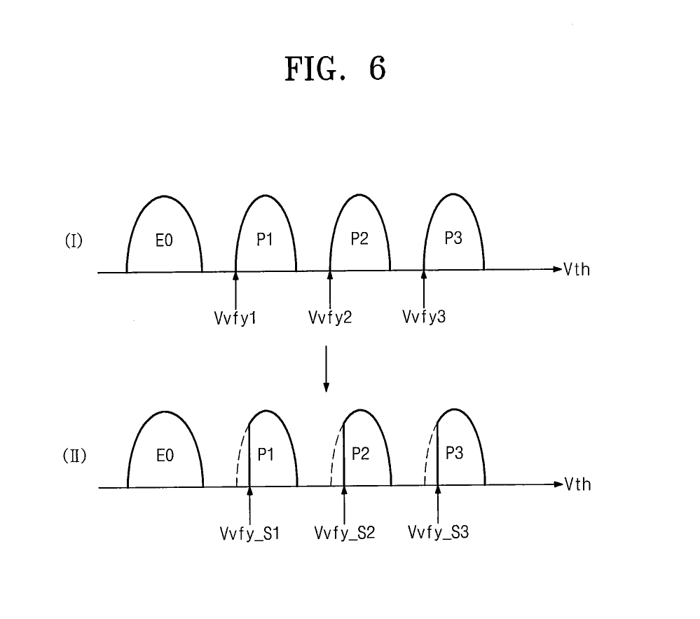

FIG. 6 is a diagram for describing effects according to some embodiments of the inventive concept. Referring to FIG. 6, there is illustrated how a threshold voltage distribution of 2-bit multi-level cells is bettered through a supplementary program operation.

In FIG. 6, the top (I) shows threshold voltage distributions of memory cells formed after a normal program operation. Threshold voltages of memory cells programmed to each of target states P1, P2, and P3 decrease due to the above-described rearrangement, retention characteristic, and charge leakage.

In FIG. 6, the bottom (II) shows threshold voltage distributions of memory cells formed after a supplementary program operation is performed. The supplementary program operation includes an operation of selecting memory cells and an operation of programming the selected memory cells. Memory cells, having threshold voltages lower than a first supplementary verification voltage Vvfy_S1, from among memory cells corresponding to the target state S1 are selected for the supplementary program operation. The selected memory cells that have threshold voltages lower than the first supplementary verification voltage Vvfy_S1 are programmed to have a threshold voltage higher than the first supplementary verification voltage Vvfy_S1 using a supplementary program pulse. However, a level of a first supplementary program voltage Vpgm_S1 is lower than or equal to that of a program voltage that is provided at a pass loop associated with the target state P1 at a normal program operation. Thus, the supplementary program operation may prevent threshold voltages of the selected memory cells from excessively increasing.

Further, memory cells, having threshold voltages lower than a second supplementary verification voltage Vvfy_S2, from among memory cells having the target state P2 as the target state are selected for the supplementary program operation. The selected memory cells that have threshold voltages lower than the second supplementary verification voltage Vvfy_S2 are programmed to have a threshold voltage higher than the second supplementary verification voltage Vvfy_S2 using a supplementary program pulse. Likewise, a level of a second supplementary program voltage Vpgm_S2 is lower than or equal to that of a program voltage that is provided at a pass loop associated with the second program state P2 at the normal program operation. Thus, the supplementary program operation may prevent threshold voltages of the selected memory cells from excessively increasing.

Further, memory cells, having threshold voltages lower than a third supplementary verification voltage Vvfy_S3, from among memory cells having the target state P3 as the target state are selected for the supplementary program operation. The selected memory cells that have threshold voltages lower than the third supplementary verification voltage Vvfy_S3 are programmed to have threshold voltages higher than the third supplementary verification voltage Vvfy_S3 using a supplementary program pulse. Likewise, a level of a third supplementary program voltage Vpgm_S3 is lower than or equal to that of a program voltage that is provided at a pass loop associated with the third program state P3 at the normal program operation. Thus, the supplementary program operation may prevent threshold voltages of the selected memory cells from excessively increasing.

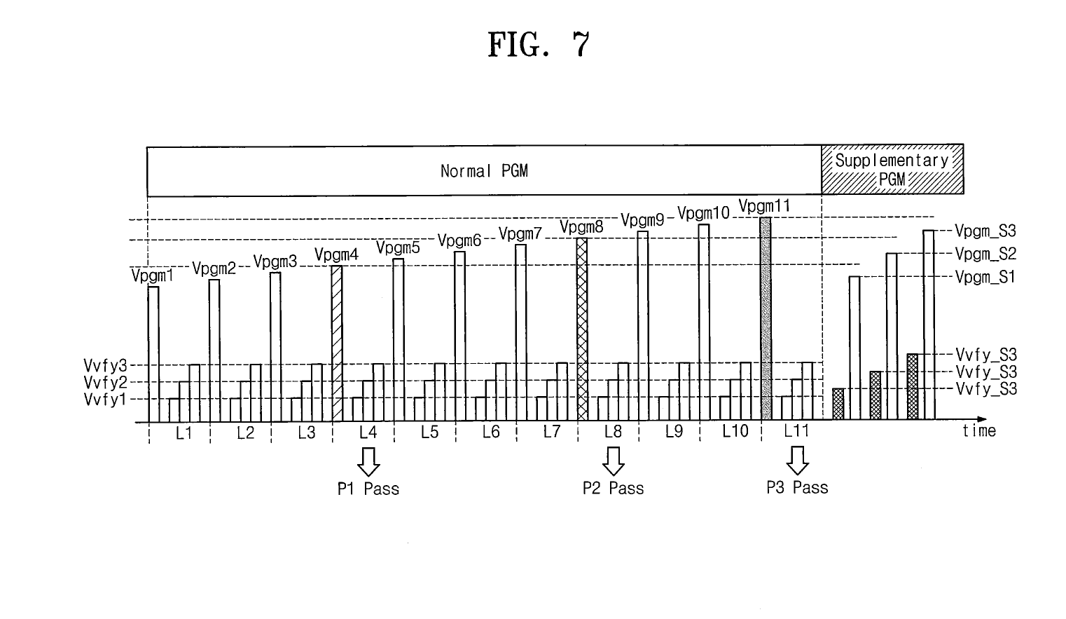

FIG. 7 is a waveform diagram showing voltages applied to a word line of memory cells to be programmed to target states shown in FIG. 6. Referring to FIG. 7, memory cells to be programmed to a plurality of target states P1, P2, and P3 are programmed via a supplementary program operation following a normal program operation.

An incremental step pulse programming manner is applied to a normal program operation. That is, program pulses Vpgm1 through VpgmN that stepwise increase are sequentially applied to a word line connected with selected memory cells. After each program pulse is applied, verification voltages Vvfy1, Vvfy2, and Vvfy3 corresponding to the target states P1, P2, and P3 are sequentially applied to the word line connected with the selected memory cells. The normal program operation is executed using a plurality of program loops. A program loop includes the applying of a program pulse and the applying of the verification voltages Vvfy1, Vvfy2, and Vvfy3.

The programming of memory cells, to be programmed to the target state P1, from among the selected memory cells is completed in a program loop corresponding to a loop count L4. The memory cells programmed to have the target state P1 are program inhibited from a program loop corresponding to a loop count L5. The programming of memory cells, to be programmed to the target state P2, from among the selected memory cells is completed in a program loop corresponding to a loop count L8. The memory cells programmed to have the target state P2 are program inhibited from a program loop corresponding to a loop count L9. The programming of memory cells, to be programmed to the target state P3, from among the selected memory cells is completed in a program loop corresponding to a loop count L11. Thus, the normal program operation associated with the target states P1, P2, and P3 is completed in a program loop corresponding to the target count L11.

At the normal program operation, a page buffer 130 (refer to FIG. 1) provides pass loop count information PLCI to control logic 150 whenever program pass about each of the program states P1, P2, and P3 is determined. For example, the page buffer 130 sends a flag signal or information to the control logic 150 when the programming of memory cells to the target state P1 is completed. The page buffer 130 sends a flag signal or information to the control logic 150 when the programming of memory cells to the target state P2 is completed. The page buffer 130 sends a flag signal or information to the control logic 150 when the programming of memory cells to the target state P3 is completed. Based on each flag signal or information, the control logic 150 determines a pass loop corresponding to each target state and selects a word line voltage for a supplementary program operation.

The supplementary program operation may be executed following the normal program operation. During the supplementary program operation, first, memory cells that necessitate the supplementary program operation are selected. It is assumed that the supplementary program operation is applied to all target states P1, P2, and P3. First, there are selected memory cells, having threshold voltages lower than a first supplementary verification voltage Vvfy_S1, from among memory cells to be programmed to the target state P1. A first supplementary program voltage Vpgm_S1 is applied to the selected memory cells. In some example embodiments, the first supplementary verification voltage Vvfy_S1 is equal to or higher than a first verification voltage Vvfy1, and the first supplementary program voltage Vpgm_S1 is equal to or lower than a program voltage Vpgm4. The program voltage Vpgm4 is a program voltage for a normal program operation that is used at a program loop where the programming of memory cells to the target state S1 is completed.

Next, there are selected memory cells, having threshold voltages lower than a second supplementary verification voltage Vvfy_S2, from among memory cells to be programmed to the target state P2. A second supplementary program voltage Vpgm_S2 is applied to the selected memory cells. In example embodiments, the second supplementary verification voltage Vvfy_S2 is equal to or higher than a second verification voltage Vvfy2, and the second supplementary program voltage Vpgm_S2 is equal to or lower than a program voltage Vpgm8. The program voltage Vpgm8 is a program voltage for a normal program operation that is used at a program loop where the programming of memory cells to the target state S2 is completed.

Then, there are selected memory cells, having threshold voltages lower than a third supplementary verification voltage Vvfy_S3, from among memory cells to be programmed to the target state P3. A third supplementary program voltage Vpgm_S3 is applied to the selected memory cells. In some example embodiments, the third supplementary verification voltage Vvfy_S2 is equal to or higher than a third verification voltage Vvfy3, and the third supplementary program voltage Vpgm_S3 is equal to or lower than a program voltage Vpgm11. The program voltage Vpgm11 is a program voltage for a normal program operation that is used at a program loop where the programming of memory cells to the target state S3 is completed.

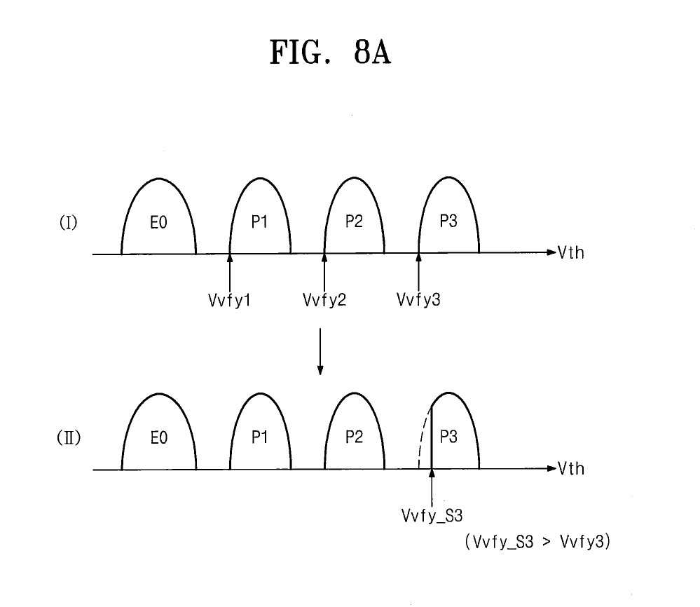

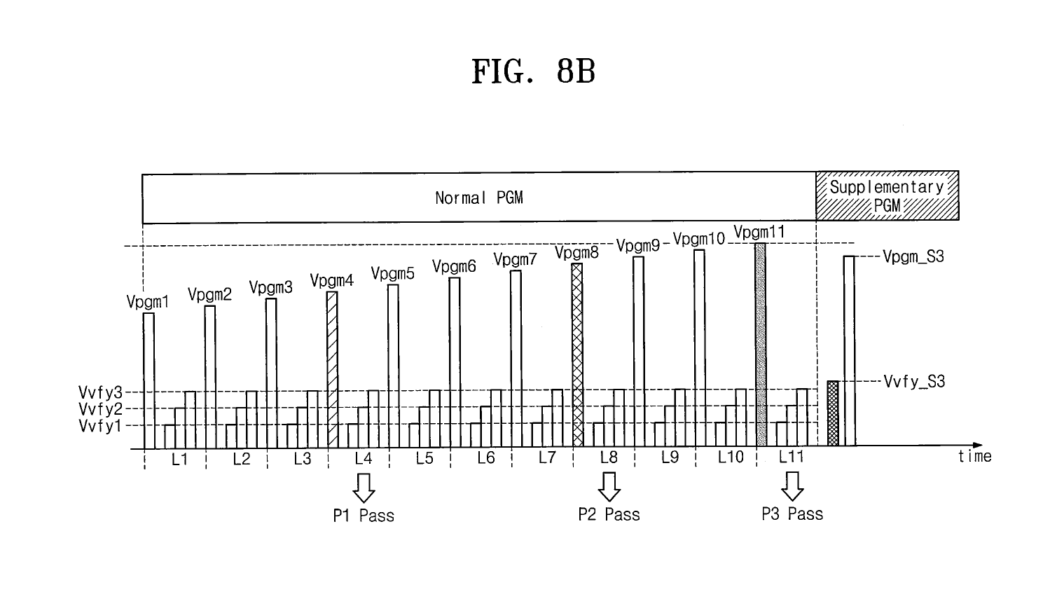

FIGS. 8A and 8B are diagrams showing a supplementary program operation about 2-bit multi-level cells, according to an embodiment of the inventive concept. Referring to FIG. 8A, one (e.g., P3) of a plurality of target states P1, P2, and P3 is selected for a supplementary program operation. A part of memory cells to be programmed to the selected target state P3 is selected.

In FIG. 8A, the top (I) shows threshold voltage distributions of memory cells formed immediately after a normal program operation. The number of program pulses applied to form threshold voltages of memory cells programmed to the target state P1, the number of program pulses applied to form threshold voltages of memory cells programmed to the target state P2, and the number of program pulses applied to form threshold voltages of memory cells programmed to the target state P3 may be formed are different from each other. In particular, a fast cell that is programmed within a relatively short time may be programmed to a target state using the relatively small number of program pulses. A slow cell that is programmed within a relatively long time may be programmed to a target state using the relatively great number of program pulses (or, the slow cell may be supplied with the relatively great number of program pulses). Thus, a target state (e.g., P3) formed through the normal program operation is classified as a fast-cell distribution or a slow-cell distribution. Fast cells experiencing the relatively small number of program pulses are viewed as being disposed at a left side of a target distribution, and slow cells experiencing the relatively great number of program pulses are viewed as being disposed at a right side of the target distribution.

A difference between a threshold voltage distribution of fast cells and a threshold voltage distribution of slow cells may vary with target states P1, P2, and P3. The supplementary program operation may be applied to a target state where a difference between a threshold voltage distribution of fast cells and a threshold voltage distribution of slow cells is relatively great to minimize a program time.

In FIG. 8A, the bottom (II) shows an embodiment where the supplementary program operation is applied to one target state. In particular, a part of memory cells to be programmed to the highest target state S3 is selected, and the supplementary program operation is applied to the selected memory cells. Memory cells, having threshold voltages lower than a third supplementary verification voltage Vvfy_S3, from among memory cells to be programmed to the target state P3 are selected for the supplementary program operation. The selected memory cells that have threshold voltages lower than a third supplementary verification voltage Vvfy_S3 are programmed to have a threshold voltage higher than the third supplementary verification voltage Vvfy_S3 using a supplementary program pulse. However, a level of the third supplementary program voltage Vpgm_S3 is lower than or equal to that of a program voltage that is provided at a pass loop associated with the third program state P3 at a normal program operation. Thus, the supplementary program operation may prevent threshold voltages of the selected memory cells from excessively increasing.

FIG. 8B is a waveform diagram showing program pulses associated with memory cells the threshold voltages of which form threshold voltage distributions shown in FIG. 8A. Referring to FIG. 8B, memory cells, corresponding to a target state P3, from among memory cells to be programmed to a plurality of target states P1, P2, and P3 through a normal program operation are selected. A part of the selected memory cells is selected for a supplementary program operation.

An incremental step pulse programming manner is applied to a normal program operation. That is, program pulses Vpgm1 through VpgmN that stepwise increase are sequentially applied to a word line connected with selected memory cells. After each program pulse is applied, verification voltages Vvfy1, Vvfy2, and Vvfy3 corresponding to the target states P1, P2, and P3 are sequentially applied to the word line connected with the selected memory cells. The normal program operation is executed using a plurality of program loops.

The programming of memory cells, to be programmed to the target state P1, from among the selected memory cells is completed in a program loop corresponding to a loop count L4. The memory cells programmed to have the target state P1 are program inhibited from a program loop corresponding to a loop count L5. The programming of memory cells, to be programmed to the target state P2, from among the selected memory cells is completed in a program loop corresponding to a loop count L8. The memory cells programmed to have the target state P2 are program inhibited from a program loop corresponding to a loop count L9. The programming of memory cells, to be programmed to the target state P3, from among the selected memory cells is completed in a program loop corresponding to a loop count L11. Thus, the normal program operation associated with the target states P1, P2, and P3 is completed in a program loop corresponding to the target count L11.

At the normal program operation, a page buffer 130 (refer to FIG. 1) provides pass loop count information PLCI to control logic 150 whenever program pass about each of the program states P1, P2, and P3 is determined. For example, the page buffer 130 sends a flag signal or information to the control logic 150 when the programming of memory cells to the target state P1 is completed. The page buffer 130 sends a flag signal or information to the control logic 150 when the programming of memory cells to the target state P2 is completed. The page buffer 130 sends a flag signal or information to the control logic 150 when the programming of memory cells to the target state P3 is completed. Based on each flag signal or information, the control logic 150 determines a pass loop corresponding to each target state and selects a word line voltage for a supplementary program operation. However, when memory cells corresponding to the target state P3 are processed according to the supplementary program operation, the page buffer 130 may provide the control logic 150 with loop count information about a program loop where the programming of memory cells to the target state P3 is completed.

The supplementary program operation may be executed following the normal program operation. During the supplementary program operation, first, memory cells that necessitate the supplementary program operation are selected. When the supplementary program operation is applied to the target state P3, memory cells, having threshold voltages lower than a third supplementary verification voltage Vvfy_S3, from among memory cells to be programmed to the target state P3 are selected. A third supplementary program voltage Vpgm_S3 is applied to the selected memory cells. In some example embodiments, the third supplementary verification voltage Vvfy_S3 is equal to or higher than a third verification voltage Vvfy3, and the third supplementary program voltage Vpgm_S3 is equal to or lower than a program voltage Vpgm11. The program voltage Vpgm11 is a program voltage for a normal program operation that is used at a program loop where the programming of memory cells to the target state P3 is completed.

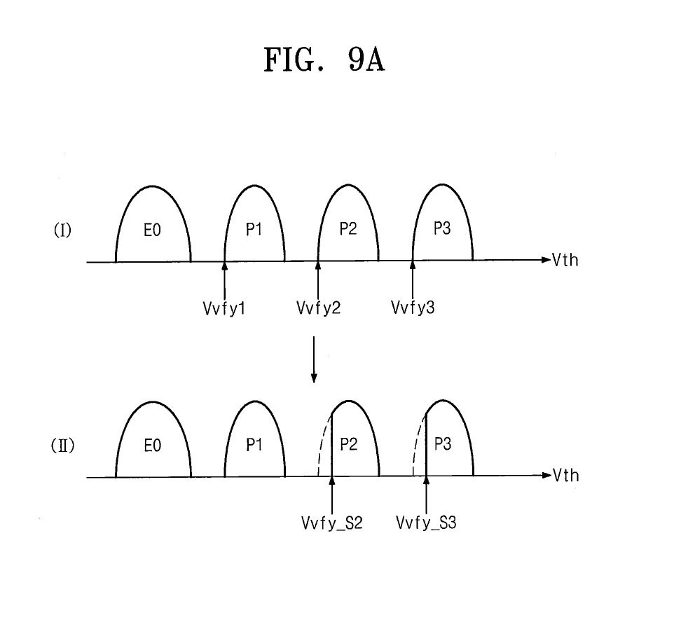

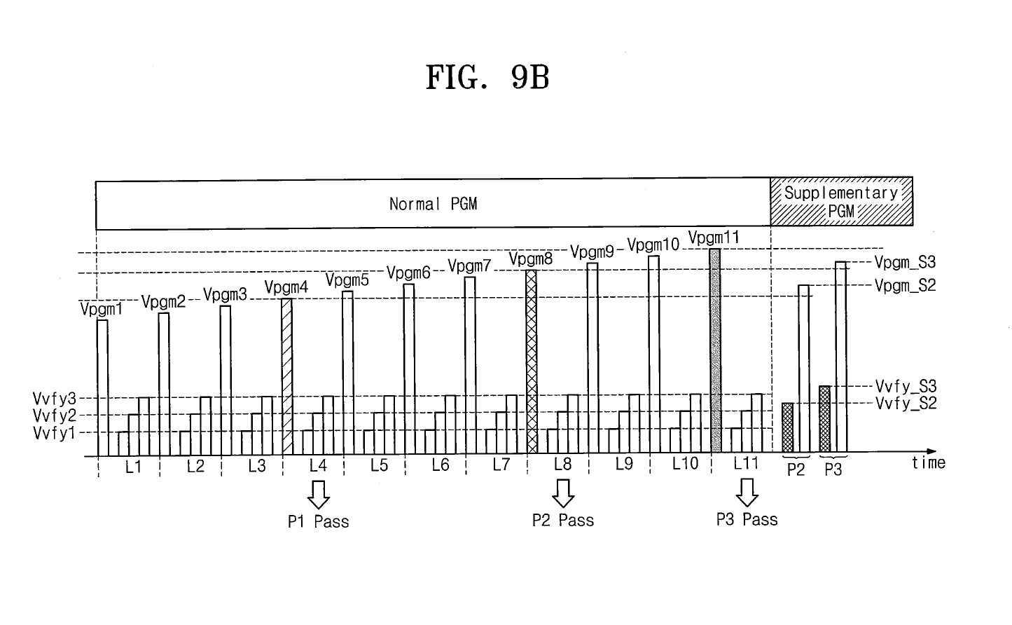

FIGS. 9A and 9B are diagrams showing a supplementary program operation about 2-bit multi-level cells, according to another embodiment of the inventive concept. Referring to FIG. 9A, two (e.g., P2 and P3) of a plurality of target states P1, P2, and P3 are selected for a supplementary program operation. A part of memory cells to be programmed to the selected target states P2 and P3 are selected.

In FIG. 9A, the top (I) shows threshold voltage distributions of memory cells formed immediately after a normal program operation. The supplementary program operation is applied to the target states P2 and P3 to minimize a program time.

In FIG. 9A, the bottom (II) shows embodiments in which the supplementary program operation is applied to two target states P2 and P3. Memory cells, having threshold voltages lower than a second supplementary verification voltage Vvfy_S2, from among memory cells to be programmed to the target state P2 are selected for the supplementary program operation. The selected memory cells that have threshold voltages lower than a second supplementary verification voltage Vvfy_S2 are programmed to have a threshold voltage higher than or equal to the second supplementary verification voltage Vvfy_S2 using a supplementary program pulse. However, a level of the second supplementary program voltage Vpgm_S2 is lower than or equal to that of a program voltage that is provided at a pass loop associated with the second program state P2 at a normal program operation.

Next, memory cells, having threshold voltages lower than a third supplementary verification voltage Vvfy_S3, from among memory cells to be programmed to the target state P3 are selected for the supplementary program operation. The selected memory cells that have threshold voltages lower than a third supplementary verification voltage Vvfy_S3 are programmed to have a threshold voltage higher than or equal to the third supplementary verification voltage Vvfy_S3 using a supplementary program pulse. However, a level of the third supplementary program voltage Vpgm_S3 is lower than or equal to that of a program voltage that is provided at a pass loop associated with the third program state P3 at a normal program operation.

FIG. 9B is a waveform diagram showing program pulses associated with memory cells the threshold voltages of which form threshold voltage distributions shown in FIG. 9A. Referring to FIG. 9B, memory cells, corresponding to target states P2 and P3, from among memory cells to be programmed to a plurality of target states P1, P2, and P3 through a normal program operation are selected. A part of the selected memory cells is selected using supplementary verification voltages Vvfy_S2 and Vvfy_S3 and is then programmed.

An incremental step pulse programming manner is applied to a normal program operation. That is, program pulses Vpgm1 through VpgmN that stepwise increase are sequentially applied to a word line connected with selected memory cells. After each program pulse is applied, verification voltages Vvfy1, Vvfy2, and Vvfy3 corresponding to the target states P1, P2, and P3 are sequentially applied to the word line connected with the selected memory cells. The normal program operation is executed using a plurality of program loops.

The programming of memory cells, to be programmed to the target state P1, from among the selected memory cells is completed in a program loop corresponding to a loop count L4. The memory cells programmed to have the target state P1 are program inhibited from a program loop corresponding to a loop count L5. The programming of memory cells, to be programmed to the target state P2, from among the selected memory cells is completed in a program loop corresponding to a loop count L8. The memory cells programmed to have the target state P2 are program inhibited from a program loop corresponding to a loop count L9. The programming of memory cells, to be programmed to the target state P3, from among the selected memory cells is completed in a program loop corresponding to a loop count L11. Thus, the normal program operation associated with the target states P1, P2, and P3 is completed in a program loop corresponding to the target count L11.

At the normal program operation, a page buffer 130 (refer to FIG. 1) provides pass loop count information PLCI to control logic 150 whenever program pass about each of the program states P1, P2, and P3 is determined. Based on each flag signal or information, the control logic 150 determines a pass loop corresponding to each target state and selects a word line voltage for a supplementary program operation. However, when the supplementary program operation is applied to memory cells corresponding to the target states P2 and P3, the page buffer 130 may skip an operation for providing loop count information about a program loop where the programming of memory cells to the target state P1 is completed.

The supplementary program operation may be executed following the normal program operation. During the supplementary program operation, first, memory cells that necessitate the supplementary program operation are selected. When the supplementary program operation is applied to the target state P2, memory cells, having threshold voltages lower than a second supplementary verification voltage Vvfy_S2, from among memory cells to be programmed to the target state P2 are selected. A second supplementary program voltage Vpgm_S2 is applied to the selected memory cells. In some example embodiments, the second supplementary verification voltage Vvfy_S2 is equal to or higher than a second verification voltage Vvfy2, and the second supplementary program voltage Vpgm_S2 is equal to or lower than a program voltage Vpgm8. The program voltage Vpgm8 is a program voltage for a normal program operation that is used at a program loop where the programming of memory cells to the target state S2 is completed.

Next, when the supplementary program operation is applied to the target state P3, memory cells, having threshold voltages lower than a third supplementary verification voltage Vvfy_S3, from among memory cells to be programmed to the target state P3 are selected. A third supplementary program voltage Vpgm_S3 is applied to the selected memory cells. In some example embodiments, the third supplementary verification voltage Vvfy_S3 is equal to or higher than a third verification voltage Vvfy3, and the third supplementary program voltage Vpgm_S3 is equal to or lower than a program voltage Vpgm11. The program voltage Vpgm11 is a program voltage for a normal program operation that is used at a program loop where the programming of memory cells to the target state S3 is completed.

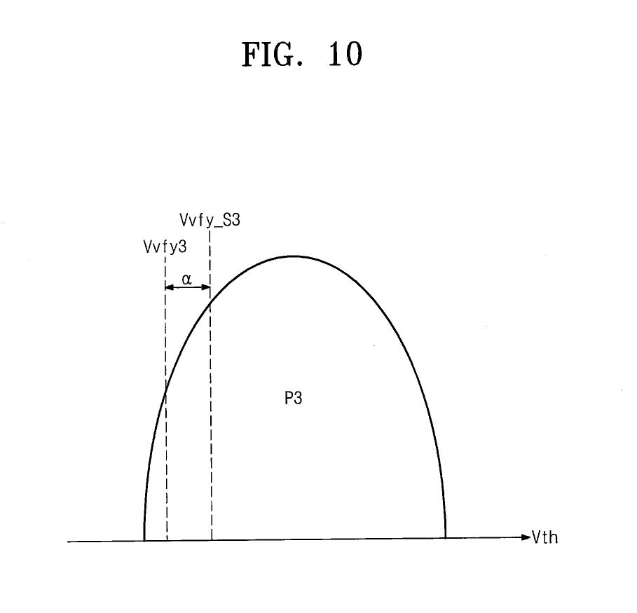

FIG. 10 is a diagram showing a method of selecting memory cells to which a supplementary program operation according to an embodiment of the inventive concept is applied. Referring to FIG. 10, there are illustrated a target state P3 as a threshold voltage distribution of memory cells formed through a normal program operation and a distribution of memory cells, selected for a supplementary program operation, from among memory cells programmed to the target state P3.

When the normal program operation is completed, threshold voltages of memory cells programmed to the target state P3 are formed as illustrated in FIG. 10. During the normal program operation, a pulse for ISPP and a third verification voltage Vvfy3 are applied to the memory cells programmed to the target state P3. When a verification result corresponding to program pass is detected in any program loop, the selected memory cells are distributed as illustrated in FIG. 10. Program-completed memory cells may include at least one memory cell that has a threshold voltage lower than the third verification voltage Vvfy3. This phenomenon may occur due to, for example, high-speed rearrangement. In some embodiments, a verification voltage scheme for preventing the number of program loops from excessively increasing may be applied in the light of memory cells that are programmed at excessively slow program speed. This verification may cause memory cells having threshold voltages lower than the third verification voltage Vvfy3 to exist even after program pass.

However, a third supplementary verification voltage Vvfy_S3 that is higher than the third verification voltage Vvfy3 is applied to selected memory cells for the supplementary program operation. A level of the third supplementary verification voltage Vvfy_S3 may be greater by a (a being a real number more than 0) than that of the third verification voltage Vvfy3. Memory cells selected using the third supplementary verification voltage Vvfy_S3 are programmed to the target state P3, but are memory cells that necessitate the relatively small number of program loops due to relatively fast program speed. Some embodiments provide that memory cells that are placed at a lower side of the target state P3 may be selected by the third supplementary verification voltage Vvfy_S3 because the relatively great number of program loops is applied to the memory cells placed at the lower side of the target state P3 due to excessively slow program speed. However, it is understood that a characteristic of memory cells selected using the third supplementary verification voltage Vvfy_S3 is not limited to the above described.

Memory cells, selected for the supplementary program operation, from among memory cells to be programmed to the target state P3 and a supplementary verification voltage Vvfy_S3 applied thereto are described. However, the scope and spirit of the inventive concept may not be limited thereto. Supplementary verification voltages Vvfy_S2 and Vvfy_S3 may be selected which correspond to target states P1 and P2. However, a supplementary verification voltage associated with a corresponding target state may be higher than a verification voltage corresponding to the target state.

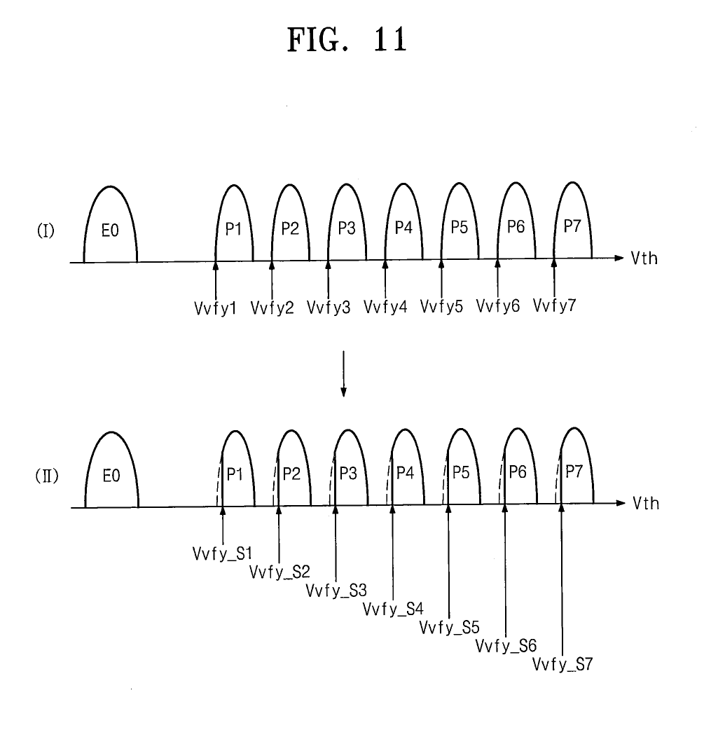

FIG. 11 is a diagram for describing how threshold voltage distributions of 3-bit multi-level cells are improved through a supplementary program operation. Referring to FIG. 11, there are illustrated threshold voltage distributions of memory cells that are programmed to seven target states P1 through P7 through a normal program operation and a supplementary program operation.

In FIG. 11, the top (I) shows threshold voltage distributions of memory cells that are formed after the normal program operation. Memory cells are programmed to have the target states P1 through P7. Even though the same program pulse is applied to memory cells through a word line, memory cells to be programmed to the target states P1 through P7 are program passed in different program loops. Loop counts of program loops where the target states P1 through P7 are program passed may be different from each other.

When the supplementary program operation is applied to memory cells the threshold voltages of which form threshold voltage distributions illustrated at the top (I) of FIG. 11, threshold voltages of the memory cells form threshold voltage distributions illustrated at the bottom (II) of FIG. 11. Memory cells, having threshold voltages lower than a first supplementary verification voltage Vvfy_S1 (higher than or equal to Vvfy1), from among memory cells to be programmed to the target state P1 are selected for the supplementary program operation. The memory cells thus selected are programmed by a supplementary program pulse to have a threshold voltage higher than the first supplementary verification voltage Vvfy_S 1. At this time, a level of the first supplementary program voltage Vpgm_S1 is lower than or equal to that of a program voltage that is provided at a pass loop associated with the target state P1 at a normal program operation.

Memory cells, having threshold voltages lower than a second supplementary verification voltage Vvfy_S2 (higher than or equal to Vvfy2), from among memory cells to be programmed to the target state P2 are selected for the supplementary program operation. The memory cells thus selected are programmed by a supplementary program pulse to have a threshold voltage higher than the second supplementary verification voltage Vvfy_S2. At this time, a level of the second supplementary program voltage Vpgm_S2 is lower than or equal to that of a program voltage that is provided at a pass loop associated with the second program state P2 at a normal program operation, thereby making it possible to prevent threshold voltages of memory cells from excessively increasing due to the supplementary program voltage.

Memory cells to be programmed to the target states P3 through P7 are selected using supplementary verification voltages Vvfy_S3 through Vvfy_S7. Supplementary program voltages Vpgm_S3 through Vpgm_S7 corresponding to the target states P3 through P7 are applied to a word line connected with the selected word line, respectively. A supplementary verification voltage Vvfy_Sj (j indicating a number of a target state) may be set to be higher than or equal to a verification voltage Vvfyj that is provided at a normal program operation. Each supplementary program voltage may be set to be equal to or lower than a program pulse voltage of a program loop where a corresponding target state is program passed at a normal program operation.

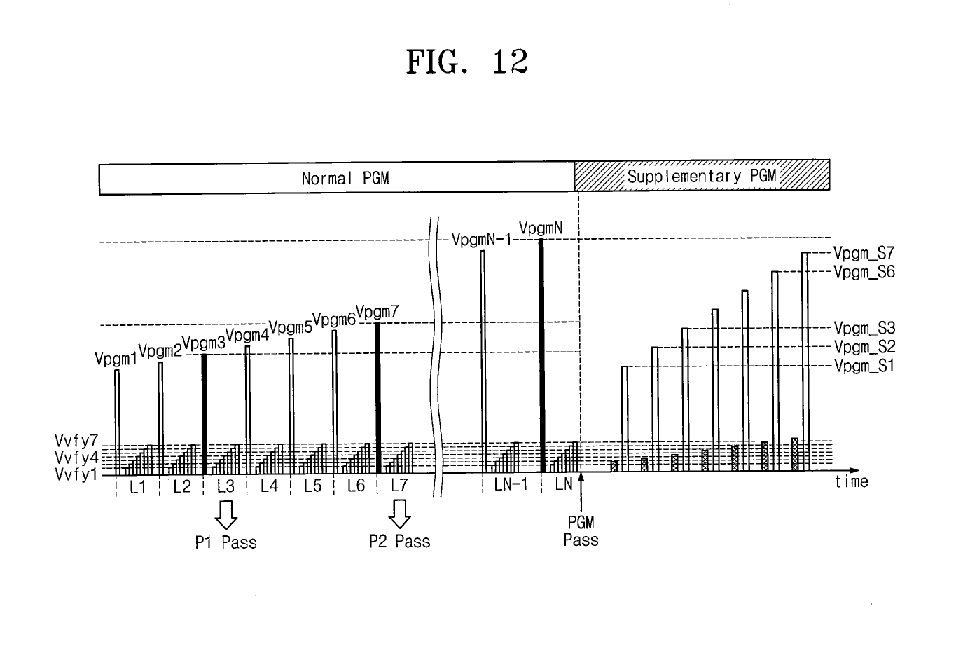

FIG. 12 is a waveform diagram showing program voltages to be applied to memory cells having target states shown in FIG. 11. Memory cells that will be programmed to have a plurality of target states P1 through P7 are programmed through a normal program operation and a following supplementary program operation.

An incremental step pulse programming manner is applied to the normal program operation. That is, program pulses Vpgm1 through VpgmN that stepwise increase are sequentially applied to a word line connected with selected memory cells. After each program pulse is applied, verification voltages Vvfy1, Vvfy2, Vvfy3, Vvfy4, Vvfy5, Vvfy6, and Vvfy7 corresponding to the target states P1, P2, P3, P4, P5, P6, and P7 are sequentially applied to the word line connected with the selected memory cells. The normal program operation is executed using a plurality of program loops.

The programming of memory cells, to be programmed to the target state P1, from among the selected memory cells is completed in a program loop corresponding to a loop count L3. The memory cells programmed to have the target state P1 are program inhibited from a program loop corresponding to a loop count L4. The programming of memory cells, to be programmed to the target state P2, from among the selected memory cells is completed in a program loop corresponding to a loop count L7. The memory cells programmed to have the target state P2 are program inhibited from a program loop corresponding to a loop count L8.

Although not shown in figures, memory cells to be programmed to each of the target states P3, P4, P5, P6, and P7 may be program passed in a program loop corresponding to any loop count as the number program loops increases. At the normal program operation, a page buffer 130 (refer to FIG. 1) provides pass loop count information PLCI to control logic 150 whenever program pass about each of the program states P1, P2, P3, P4, P5, P6, and P7 is determined. The pass loop count information PLCI is provided to the control logic 150 by means of a flag signal or data. Based on the flag signal or information corresponding to each target state, the control logic 150 determines a pass loop corresponding to each target state and selects a word line voltage for a supplementary program operation.

Executed is the supplementary program operation following the normal program operation. During the supplementary program operation, first, memory cells that necessitate the supplementary program operation are selected. When the supplementary program operation is applied to the target states P1, P2, P3, P4, P5, P6, and P7, memory cells, having threshold voltages lower than a first supplementary verification voltage Vvfy_S1, from among memory cells to be programmed to the target state P1 are selected. A first supplementary program voltage Vpgm_S1 is applied to the selected memory cells. In some example embodiments, the first supplementary verification voltage Vvfy_S1 is equal to or higher than a first verification voltage Vvfy1, and the first supplementary program voltage Vpgm_S1 is equal to or lower than a program voltage Vpgm3. The program voltage Vpgm3 is a program voltage for a normal program operation that is used at a program loop where the programming of memory cells to the target state P1 is completed.

Memory cells, having threshold voltages lower than a second supplementary verification voltage Vvfy_S2, from among memory cells to be programmed to the target state P2 are selected. A second supplementary program voltage Vpgm_S2 is applied to the selected memory cells. In some example embodiments, the second supplementary verification voltage Vvfy_S2 is equal to or higher than a second verification voltage Vvfy2, and the second supplementary program voltage Vpgm_S2 is equal to or lower than a program voltage Vpgm7. The program voltage Vpgm7 is a program voltage for a normal program operation that is used at a program loop where the programming of memory cells to the target state P2 is completed.

Memory cells, having threshold voltages lower than a third supplementary verification voltage Vvfy_S3, from among memory cells to be programmed to the target state P3 are selected. A third supplementary program voltage Vpgm_S3 is applied to the selected memory cells. In some example embodiments, the third supplementary verification voltage Vvfy_S3 is equal to or higher than a third verification voltage Vvfy3. Although not shown in FIG. 12, the third supplementary program voltage Vpgm_S3 is equal to or lower than a program voltage for a normal program operation that is used at a program loop where the programming of memory cells to the target state P3 is completed.

The supplementary program operation may be executed with respect to the target states P4, P5, P6, and P7 in the same manner as described above.

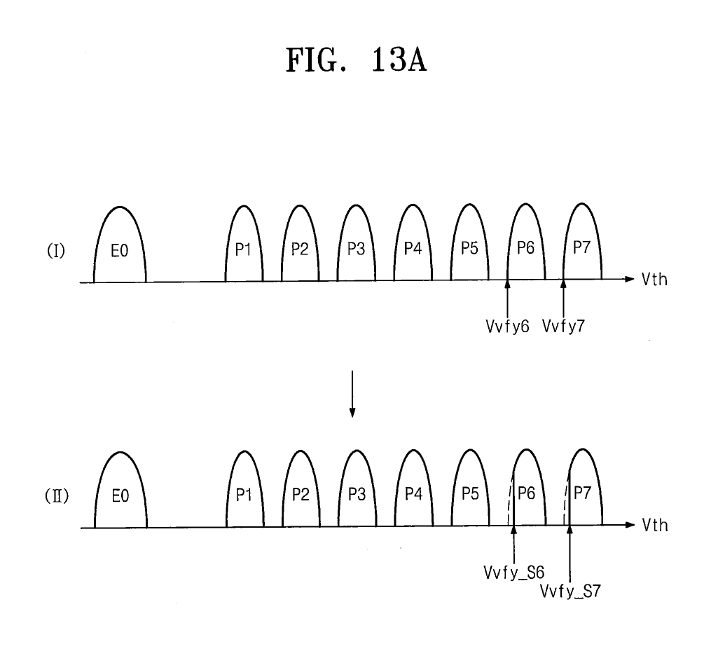

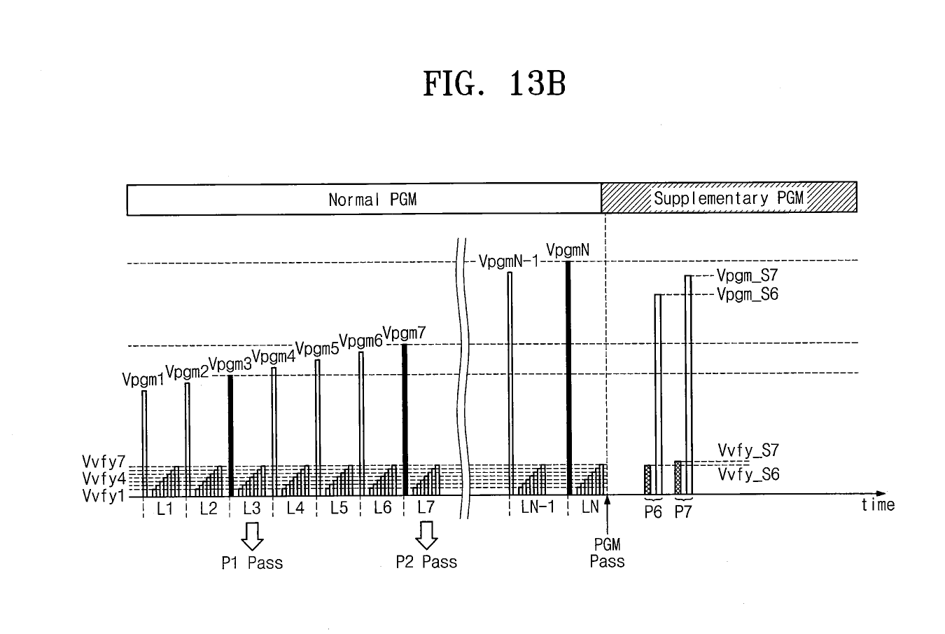

FIGS. 13A and 13B are diagrams showing embodiments in which a supplementary program operation is applied to a part of target states of 3-bit multi-level cells.

Referring to FIG. 13A, a supplementary program operation is applied to memory cells having two target states P6 and P7 among seven target states P1, P2, P3, P4, P5, P6, and P7.

In FIG. 13A, the top (I) shows threshold voltage distributions of memory cells that are formed after the normal program operation. Memory cells are simultaneously programmed to the target states P1 through P7. Even though the same program pulse is applied to memory cells through a word line, memory cells to be programmed to the target states P1 through P7 are program passed in different program loops. Loop counts of program loops where the target states P1 through P7 are program passed may be different from each other.

When the supplementary program operation is applied to memory cells the threshold voltages of which form threshold voltage distributions illustrated at the top (I) of FIG. 13A, threshold voltages of the memory cells form threshold voltage distributions illustrated at the bottom (II) of FIG. 13A. Memory cells, having threshold voltages lower than a sixth supplementary verification voltage Vvfy_S6 (higher than or equal to Vvfy6), from among memory cells to be programmed to the target state P6 are selected for the supplementary program operation. The memory cells thus selected are programmed by a supplementary program pulse to have a threshold voltage higher than the sixth supplementary verification voltage Vvfy_S6. At this time, a level of the sixth supplementary program voltage Vpgm_S6 is lower than or equal to that of a program voltage that is provided at a pass loop associated with the target state P6 at a normal program operation.

Memory cells, having threshold voltages lower than a seventh supplementary verification voltage Vvfy_S7 (higher than or equal to Vvfy7), from among memory cells to be programmed to the target state P7 are selected for the supplementary program operation. The memory cells thus selected are programmed by a supplementary program pulse to have a threshold voltage higher than the seventh supplementary verification voltage Vvfy_S7. At this time, a level of the seventh supplementary program voltage Vpgm_S7 is lower than or equal to that of a program voltage that is provided at a pass loop associated with the second program state P7 at a normal program operation.

Referring to FIG. 13B, memory cells that will be programmed to have a plurality of target states P1 through P7 are programmed through a normal program operation and a following supplementary program operation.

An incremental step pulse programming manner is applied to the normal program operation. That is, program pulses Vpgm1 through VpgmN that stepwise increase are sequentially applied to a word line connected with selected memory cells. After each program pulse is applied, verification voltages Vvfy1, Vvfy2, Vvfy3, Vvfy4, Vvfy5, Vvfy6, and Vvfy7 corresponding to the target states P1, P2, P3, P4, P5, P6, and P7 are sequentially applied to the word line connected with the selected memory cells. The normal program operation is executed using a plurality of program loops.

The programming of memory cells, to be programmed to the target state P1, from among the selected memory cells is completed in a program loop corresponding to a loop count L3. The memory cells programmed to have the target state P1 are program inhibited from a program loop corresponding to a loop count L4. The programming of memory cells, to be programmed to the target state P2, from among the selected memory cells is completed in a program loop corresponding to a loop count L7. The memory cells programmed to have the target state P2 are program inhibited from a program loop corresponding to a loop count L8.

Although not shown in figures, memory cells to be programmed to each of the target states P3, P4, P5, P6, and P7 may be program passed in a program loop corresponding to any loop count as the number program loops increases. At the normal program operation, a page buffer 130 (refer to FIG. 1) provides pass loop count information PLCI to control logic 150 whenever program pass about each of the program states P1, P2, P3, P4, P5, P6, and P7 is determined. The pass loop count information PLCI is provided to the control logic 150 by means of a flag signal or data. Based on the flag signal or information corresponding to each target state, the control logic 150 determines a pass loop corresponding to each target state and selects a word line voltage for a supplementary program operation.

The supplementary program operation may be executed following the normal program operation. During the supplementary program operation, first, memory cells that necessitate the supplementary program operation are selected. When the supplementary program operation is applied to two target states P6 and P7 of the target states P1, P2, P3, P4, P5, P6, and P7, memory cells, having threshold voltages lower than a sixth supplementary verification voltage Vvfy_S6, from among memory cells to be programmed to the target state P1 are selected. A sixth supplementary program voltage Vpgm_S6 is applied to the selected memory cells. In some example embodiments, the sixth supplementary verification voltage Vvfy S6 is equal to or higher than a sixth verification voltage Vvfy6, and the sixth supplementary program voltage Vpgm_S6 is equal to or lower than a program voltage that is used at a program loop where the programming of memory cells to the target state P6 is completed.

Memory cells, having threshold voltages lower than a seventh supplementary verification voltage Vvfy_S7, from among memory cells to be programmed to the target state P7 are selected. A seventh supplementary program voltage Vpgm_S7 is applied to the selected memory cells. In some example embodiments, the seventh supplementary verification voltage Vvfy_S7 is equal to or higher than a seventh verification voltage Vvfy7, and the seventh supplementary program voltage Vpgm_S7 is a program voltage for a normal program operation that is used at a program loop where the programming of memory cells to the target state P7 is completed.

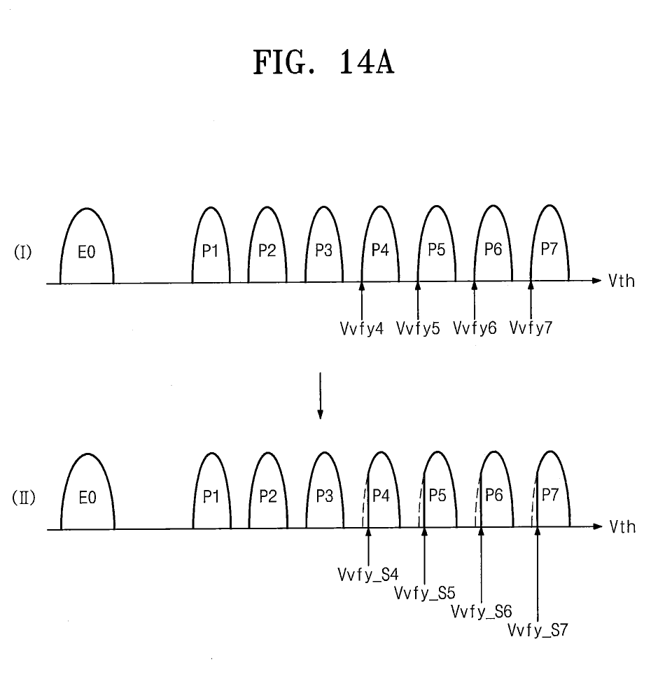

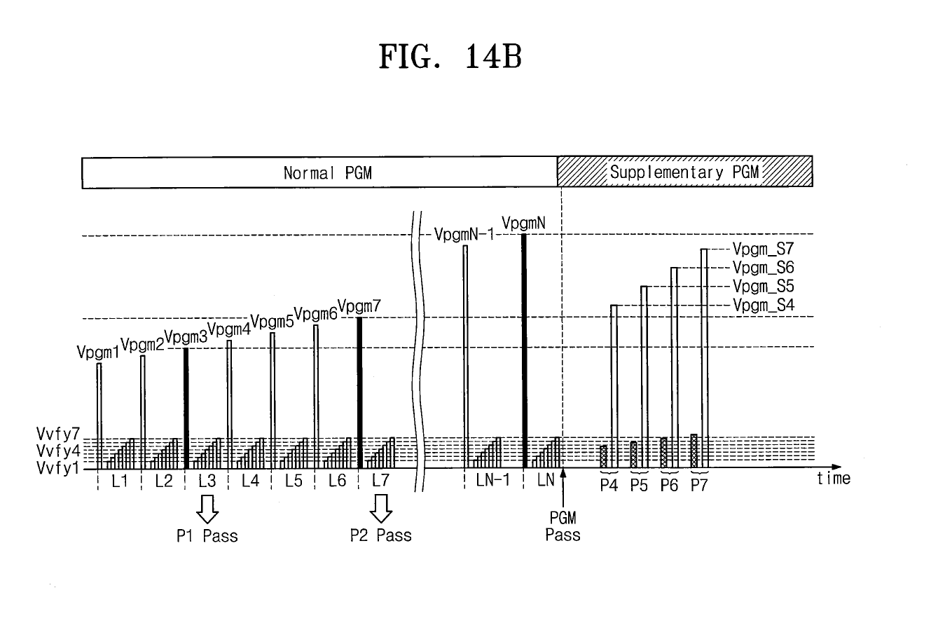

FIGS. 14A and 14B are diagrams showing some embodiments in which a supplementary program operation is applied to a part of target states of 3-bit multi-level cells.

Referring to FIG. 14A, a supplementary program operation is applied to memory cells having four target states P4, P5, P6, and P7 among seven target states P1, P2, P3, P4, P5, P6, and P7.

In FIG. 14A, the top (I) shows threshold voltage distributions of memory cells that are formed after the normal program operation. Memory cells are simultaneously programmed to the target states P1 through P7. Even though the same program pulse is applied to memory cells through a word line, memory cells to be programmed to the target states P1 through P7 are program passed in different program loops. Loop counts of program loops where the target states P1 through P7 are program passed may be different from each other.

When the supplementary program operation is applied to memory cells the threshold voltages of which form threshold voltage distributions illustrated at the top (I) of FIG. 14A, threshold voltages of the memory cells form threshold voltage distributions illustrated at the bottom (II) of FIG. 14A. Memory cells, having threshold voltages lower than a fourth supplementary verification voltage Vvfy_S4 (higher than or equal to Vvfy4), from among memory cells to be programmed to the target state P4 are selected for the supplementary program operation. The memory cells thus selected are programmed by a supplementary program pulse to have a threshold voltage higher than the fourth supplementary verification voltage Vvfy_S4. At this time, a level of the fourth supplementary program voltage Vpgm_S4 is lower than or equal to that of a program voltage that is provided at a pass loop associated with the target state P4 at a normal program operation.

Memory cells, having threshold voltages lower than a fifth supplementary verification voltage Vvfy_S5 (higher than or equal to Vvfy5), from among memory cells to be programmed to the target state P5 are selected for the supplementary program operation. The memory cells thus selected are programmed by a supplementary program pulse to have a threshold voltage higher than the fifth supplementary verification voltage Vvfy_S5. At this time, a level of the fifth supplementary program voltage Vpgm_S5 is lower than or equal to that of a program voltage that is provided at a pass loop associated with the target state P5 at a normal program operation.

A supplementary program method of programming memory cells to the target states P6 and P7 is substantially the same as that described with reference to FIGS. 13A and 13B, and a detailed description thereof is thus omitted.

There are described supplementary program methods for programming memory cells to at least one of a plurality of target states. The supplementary program methods for one target state, two target states, or four target states is described with reference to accompanying drawings. However, the scope and spirit of the inventive concept may not be limited thereto. For example, it is understood that the supplementary program methods according to an embodiment of the inventive concept is applied to at least one any target state.

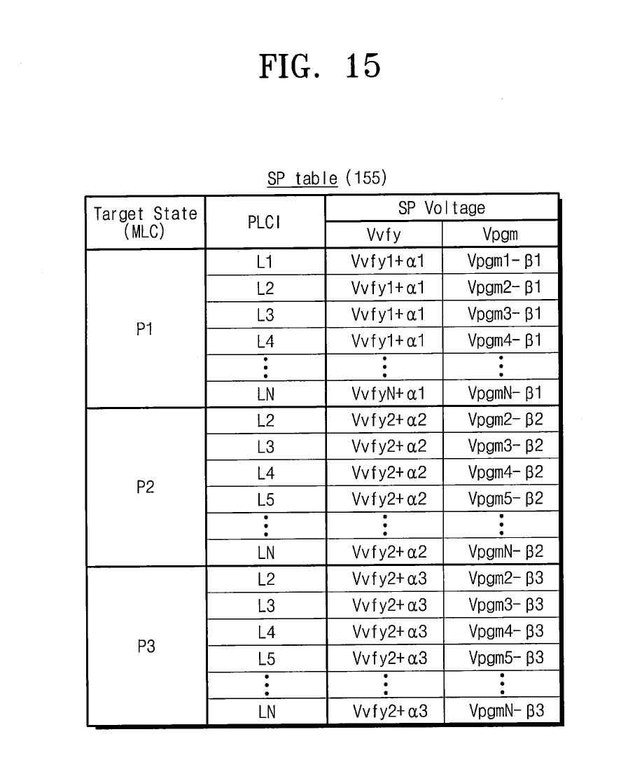

FIG. 15 is a table showing a supplementary program table 155 shown in FIG. 1, according to an embodiment of the inventive concept. Referring to FIG. 15, a supplementary program table 155 includes supplementary verification voltages Vvfy_S and supplementary program voltages Vpgm_S that correspond to pass loops associated with target states P1, P2, and P3. Information about a pass loop is provided from a page buffer 130 as pass loop count information PLCI.

At a normal program operation, the programming of memory cells to a target state P1 is completed in a program loop corresponding to a loop count L3. On this occasion, control logic 150 selects a supplementary verification voltage (Vvfy1−α1) and a supplementary program voltage (Vpgm4−β1), based on the supplementary program table 155. In some embodiments, at the normal program operation, the programming of memory cells to a target state P2 is completed in a program loop corresponding to a loop count L5. On this occasion, the control logic 150 selects a supplementary verification voltage (Vvfy2−α2) and a supplementary program voltage (Vpgm5−β2), based on the supplementary program table 155.

The supplementary verification voltage Vvfy_S that is defined in the supplementary program table 155 is higher than a verification voltage that is used at the normal program operation. The supplementary program voltage Vpgm_S may be set to be lower than a program voltage that is used in a pass loop of a corresponding target state.

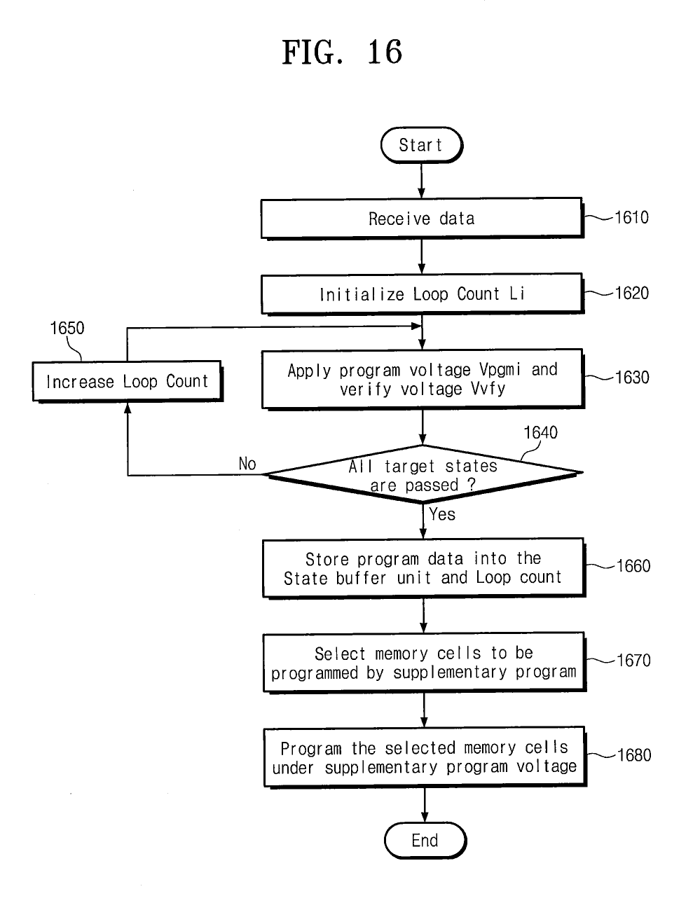

FIG. 16 is a flow chart showing a program operation according to an embodiment of the inventive concept. Referring to FIG. 16, a nonvolatile memory device 100 according to some embodiments of the inventive concept programs data, provided from an external device at a program operation, at selected memory cells through a normal program operation and a supplementary program operation.

In operation 1610, the nonvolatile memory device 100 receives a program command and data from the external device. The received data is loaded on a page buffer 130 shown in FIG. 1, and the program command is provided to control logic 150.

In operation 1620, the nonvolatile memory device 100 performs the normal program operation using an ISPP manner. In particular, the nonvolatile memory device 100 sets a loop count to an initialization value L1. Afterwards, a value of a loop count is gradually increased.

In operation 1630, the nonvolatile memory device 100 applies a program voltage Vpgmi (i indicating a loop count) to selected memory cells. Verification voltages Vvfy corresponding to plural target states are provided every program loop to program multi-level cells. Pass loop count information PLCI associated with a pass loop of each target state is sent to the control logic 150.

In operation 1640, the nonvolatile memory device 100 determines whether memory cells are programmed to have target states. For example, whether memory cells are programmed to have a selected target state P1 is determined based on a first verification voltage Vvfy1. Whether memory cells are programmed to have a selected target state P2 is determined based on a second verification voltage Vvfy2. Whether memory cells are programmed to have a selected target state P3 is determined based on a third verification voltage Vvfy3. Whether all target states are passed, that is, whether the normal program operation is passed may be determined in the above-described manner. As a consequence of determining that at least one of the target states is not passed, the methods proceed to operation 1650 to apply an increase program voltage. As a consequence of determining that all target states are passed, the methods proceed to operation 1660.

In step S250, the nonvolatile memory device 100 increases a value of a loop count and then returns to operation 1630 to execute a program operation using an increased program voltage.

In operation 1660, the nonvolatile memory device 100 stores all program data at internal latches of the page buffer 130 or at a state buffer unit 135 even after all program data is stored through the normal program operation. Pass loop count information indicating values of pass loops corresponding to target states is transferred from the page buffer 130 to the control logic 150.

In operation 1670, memory cells to which a supplementary program operation will be applied are selected. For example, the nonvolatile memory device 100 selects memory cells, corresponding to a specific target state, from among memory cells selected for programming. Memory cells, having threshold voltages lower than a supplementary verification voltage, from among the memory cells programmed to the specific target state are selected.

In operation 1680, the nonvolatile memory device 100 applies a supplementary program voltage to memory cells selected for the supplementary program operation. The nonvolatile memory device 100 provides a program voltage with respect to the selected/specific target state at the supplementary program operation. A level of the provided program voltage is lower than that of a final program pulse provided at a normal program operation. Even though memory cells are programmed using the supplementary program operation, an increase in threshold voltages of the memory cells may be set to be lower than the upper limit defined.

As described above, the nonvolatile memory device 100 performs a supplementary program operation after a normal program operation is completed. Thus, it is possible to minimize an increase in a time taken to perform a program operation and to prevent threshold voltage distributions of memory cells from deteriorating due to various factors. Some embodiments of the inventive concept are exemplified as a supplementary program operation is performed once with respect to each target state. However, the scope and spirit of the inventive concept may not be limited thereto. If needed, the number of supplementary program operations associated with each target state may increase.

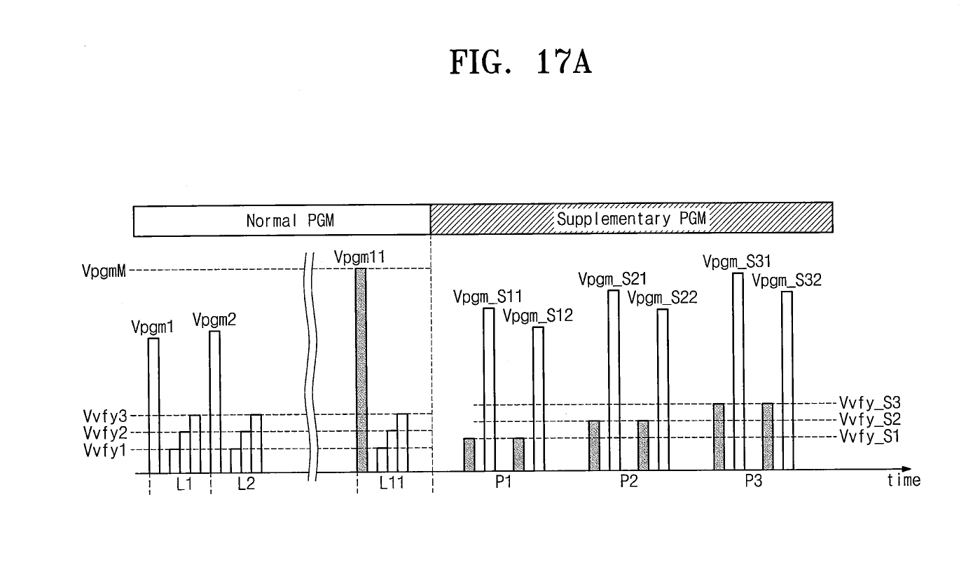

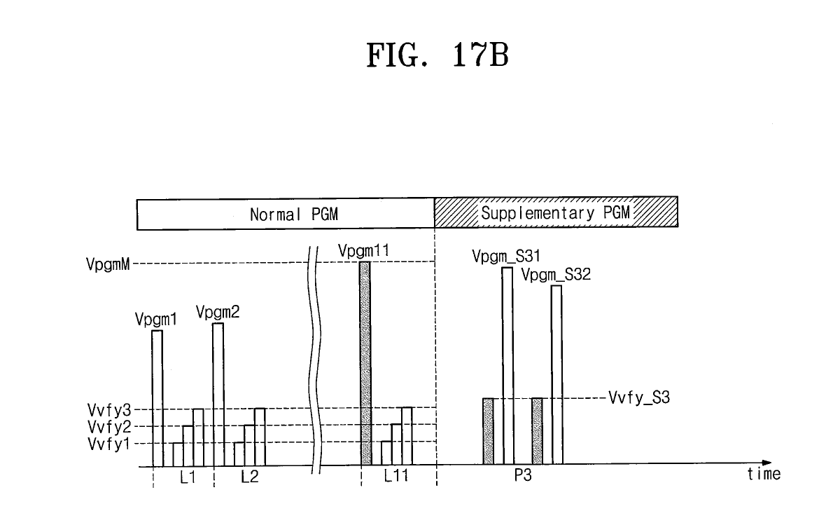

FIGS. 17A and 17B are timing diagrams showing embodiments in which the number of supplementary program operations associated with each target state is changed. In FIG. 17A, some embodiments of the inventive concept are exemplified as a supplementary program operation is performed twice with respect to each of program states P1, P2, and P3. Referring to the target state P1, a supplementary program voltage Vpgm_S11 is higher than a supplementary program voltage Vpgm_S12 that is applied following the supplementary program voltage Vpgm_S 11. This setting may be also applied to target states P2 and P3.

FIG. 17B shows embodiments in which a supplementary program operation is performed twice with respect to one of the target states P1, P2, and P3. When a supplementary program operation is applied to the target state P3, a supplementary program voltage Vpgm_S31 is higher than a supplementary program voltage Vpgm_S32 that is applied following the supplementary program voltage Vpgm_S31.

In FIGS. 17A and 17B, some embodiments of the inventive concept are exemplified as a supplementary program operation is performed in plurality with respect to one target state. Although not shown in figures, the supplementary program operation may be applied to one target state three times or more. The number of supplementary program operations associated with one target state may be determined in the light of trade-off between the number of supplementary program operations and deterioration of performance.

FIG. 18 is a diagram schematically illustrating an effect according to some embodiments of the inventive concept. Referring to FIG. 18, there are illustrated threshold voltage distributions that are changed when a supplementary program operation is applied to 3-bit multi-level cells. Threshold voltage distributions P1′, P2′, P3′, P4′, P5′, P6′, and P7′ shown in dotted line are formed after a normal program operation is performed with respect to target states P1, P2, P3, P4, P5, P6, and P7. Threshold voltage distributions P1″, P2″, P3″, P4″, P5″, P6″, and P7″ shown in solid line are formed after a supplementary program operation is performed. Even though the supplementary program operation according to some embodiments of the inventive concept is applied, memory cells having an erase state E0 are substantially unaffected.

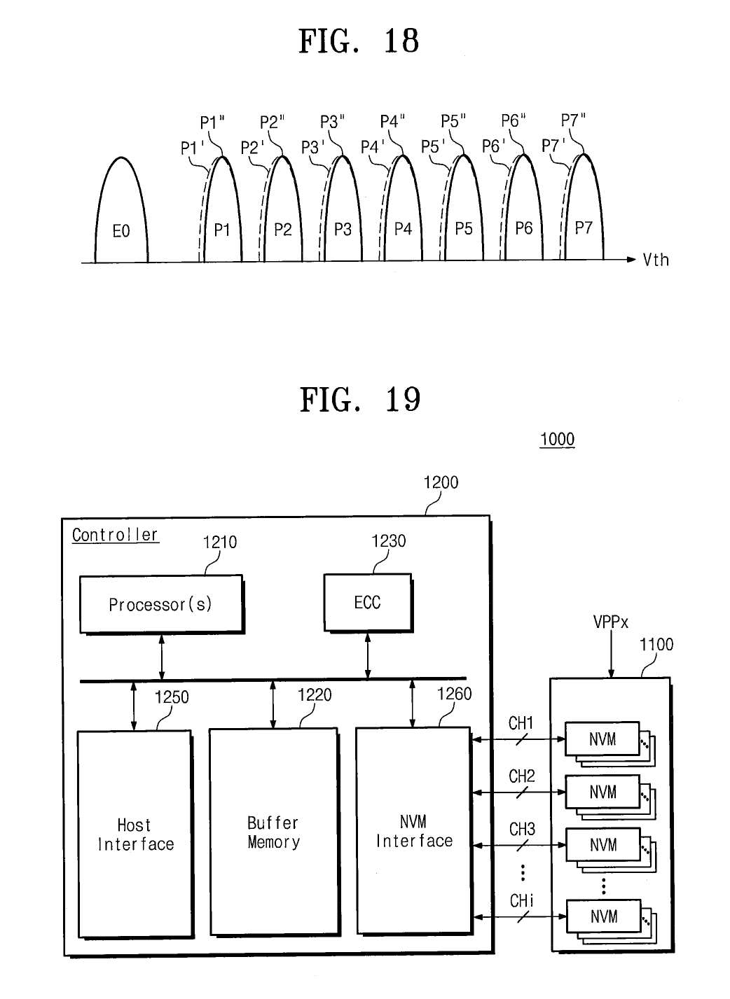

FIG. 19 is a block diagram schematically illustrating a solid state drive according to an embodiment of the inventive concept. Referring to FIG. 19, a solid state drive (hereinafter referred to as “SSD”) 1000 includes a plurality of nonvolatile memory devices 1100 and an SSD controller 1200.

The nonvolatile memory devices 1100 are provided with an external high voltage VPPx optionally. Each of the nonvolatile memory devices 1100 may be implemented with a nonvolatile memory device described with reference to FIG. 1. The SSD controller 1200 is connected to the nonvolatile memory devices 1100 through a plurality of channels CH1 through CHi (i being an integer of 2 or more).

The SSD controller 1200 includes one or more processors 1210, a buffer memory 1220, an ECC block 1230, a host interface 1250, and a nonvolatile memory interface 1260.

The buffer memory 1220 temporarily stores data needed to drive the SSD controller 1200. In some example embodiments, the buffer memory 1220 may include a plurality of memory lines each of which stores data or a command. The memory lines may be mapped onto cache lines in various manners. The buffer memory 1220 may store page bitmap information and read count information. The page bitmap information and read count information may be read from the nonvolatile memory device 1100 and may be updated according to an internal operation. The updated page bitmap information and read count information may be stored at the nonvolatile memory device 1100 periodically or randomly.

The ECC block 1230 calculates an ECC value of data to be programmed at a write operation, corrects an error of read data according to an ECC value at a read operation, and corrects an error of data restored from the nonvolatile memory device 1100 at a data restoration operation. Although not shown in FIG. 19, a code memory may be further included to store code data needed to drive the SSD controller 1200. The code memory may be implemented with a nonvolatile memory device.

The host interface 1250 provides an interface with an external device. The host interface 1250 may be a NAND flash interface. Besides, the host interface 1250 may be implemented with various interfaces or with a plurality of interfaces. The nonvolatile memory interface 1260 provides an interface with the nonvolatile memory devices 1100.

The SSD 1000 according to some embodiments of the inventive concept includes the nonvolatile memory devices 1100 to which a supplementary program operation is applied, thereby making integrity of data high.

The inventive concept is applicable to an eMMC (e.g., an embedded multimedia card, moviNAND, iNAND, etc.).

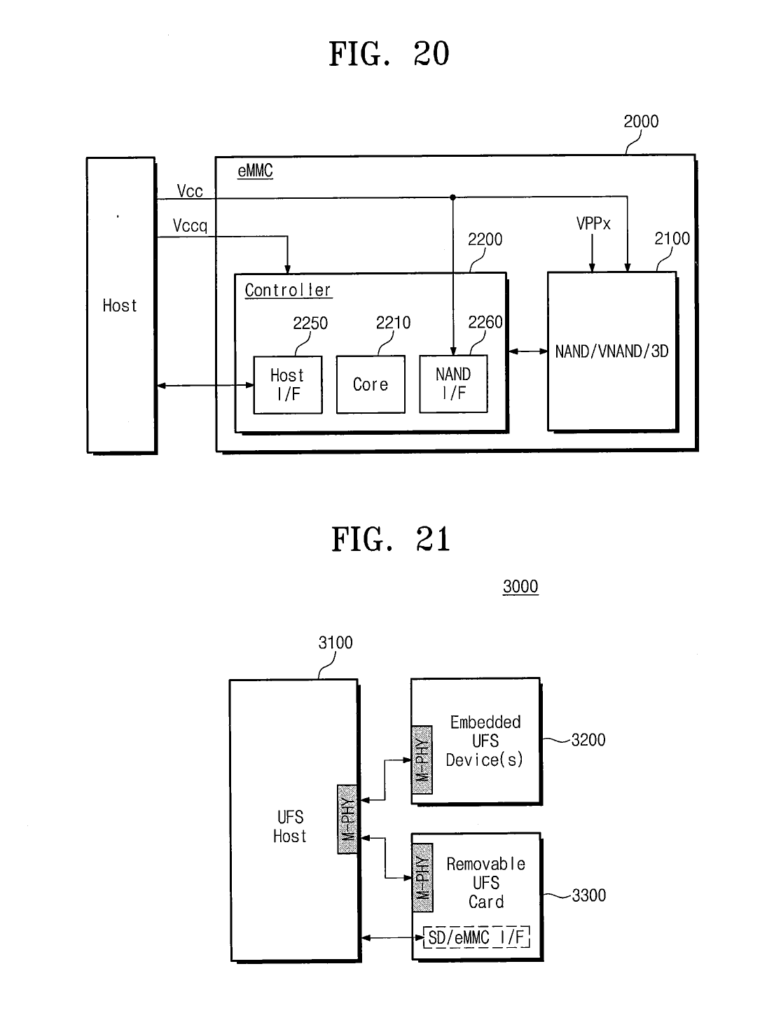

FIG. 20 is a block diagram schematically illustrating an eMMC according to an embodiment of the inventive concept. Referring to FIG. 20, an eMMC 2000 includes one or more NAND flash memory devices 2100 and a controller 2200. The NAND flash memory device 2100 may be implemented with a nonvolatile memory device described with reference to FIG. 1. The controller 2200 is connected to the NAND flash memory device 2100 via a plurality of channels.

The controller 2200 includes one or more controller cores 2210, a host interface 2250, and a NAND interface 2260. The controller core 2210 may control an overall operation of the eMMC 2000. The host interface 2250 performs an interface between the controller 2200 and a host. The NAND interface 2260 provides an interface between the NAND flash memory device 2100 and the controller 2200. In some example embodiments, the host interface 2250 may be a parallel interface (e.g., MMC interface). In some example embodiments, the host interface 2250 of the eMMC 2000 may be a serial interface (e.g., UHS-II, UFS interface, etc.). In some example embodiments, the host interface 2250 may be a NAND interface.

The eMMC 2000 receives power supply voltages Vcc and Vccq from the host. Herein, the power supply voltage Vcc (e.g., about 3.3 V) may be supplied to the NAND flash memory device 2100 and the NAND interface 2260, and the power supply voltage Vccq (e.g., about 1.8 V/3.3 V) may be supplied to the controller 2200. In some example embodiments, the eMMC 2000 may be optionally supplied with an external high voltage.

The eMMC 2000 according to some embodiments of the inventive concept includes the NAND flash memory device 2100 that minimizes a decrease in performance and provides high integrity of data, thereby obtaining high performance and integrity of data.

The inventive concept is applicable to Universal Flash Storage UFS.

FIG. 21 is a block diagram schematically illustrating a UFS system according to some embodiments of the inventive concept. Referring to FIG. 21, a UFS system 3000 includes a UFS host 3100, an embedded UFS device 3200, and a removable UFS card 3300. Communication between the UFS host 3100 and the embedded UFS device 3200 and communication between the UFS host 3100 and the removable UFS card 3300 may be performed through M-PHY layers.

The host 3100 includes a bridge that enables the removable UFS card 3300 to communicate using the protocol different from the UFS protocol. The UFS host 3100 and the removable UFS card 3300 may communicate through various card protocols (e.g., UFDs, MMC, SD (secure digital), mini SD, Micro SD, etc.).

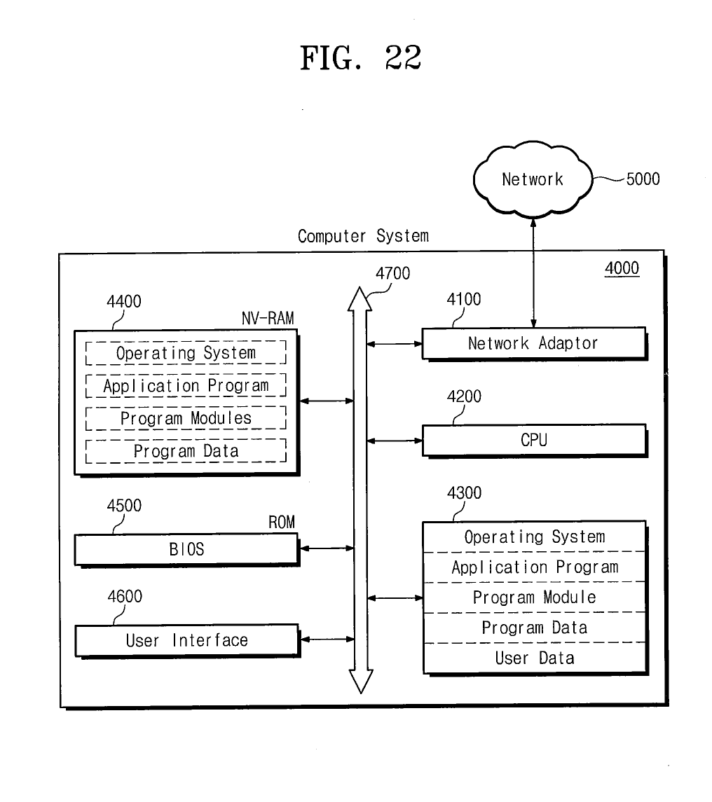

FIG. 22 is a block diagram schematically illustrating a computing system according to some embodiments of the inventive concept. Referring to FIG. 22, a computing (e.g., computer) system 4000 includes a network adaptor 4100, a central processing unit (CPU) 4200, a mass storage device 4300, a RAM 4400, a ROM 4500, and a user interface 4600 which are connected with a system bus 4700.

The network adaptor 4100 provides an interface between the computing system 4000 and external networks 5000. The CPU 4200 controls an overall operation for driving an operating system and an application program which are resident on the RAM 4400. The data storage device 4300 may store data needed for the computing system 4000. For example, the data storage device 4300 may store an operating system for driving the computing system 3000, an application program, various program modules, program data, user data, and so on.

The RAM 4400 may be used as a working memory of the computing system 4000. Upon booting, the operating system, the application program, the various program modules, and program data needed to drive programs and various program modules read out from the data storage device 4300 may be loaded onto the RAM 4400. The ROM 4500 may store a basic input/output system (BIOS) which is activated before the operating system is driven upon booting. Information exchange between the computing system 4000 and a user may be made via the user interface 4600.

In some example embodiments, the computing system 4000 may further include a battery, a modem, and so on. Although not shown, also, the computing system 4000 may further include an application chipset, a camera image processor (CIS), a mobile DRAM, and so on.

The mass storage device 4300 may be implemented with a solid state drive, a multimedia card (MMC), a secure digital (SD) card, a micro SD card, a memory stick, an ID card, a PCMCIA card, a chip card, an USB card, a smart card, a compact flash (CF) card, and so on. The mass storage device 4300 may include a nonvolatile memory device 100 shown in FIG. 1. Thus, at a program operation, the mass storage device 4300 may program data using a supplementary program operation.

A semiconductor device according to the inventive concept may be packaged according to any of a variety of different packaging technologies. Examples of such packaging technologies may include the following: PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), and/or Wafer-Level Processed Stack Package (WSP).

In some embodiments of the inventive concept, a nonvolatile memory device is provided which minimizes a program time taken to better threshold voltage distributions and minimizes the drooping and spreading of threshold voltage distributions of memory cells. Thus, it is possible to implement a nonvolatile memory device that has high reliability without lowering performance.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative.

1. A method of programming a nonvolatile memory device, comprising:
programming a plurality of memory cells to a target state using a verification voltage and incremental step pulses;
selecting ones of the plurality of memory cells, each having a threshold voltage lower than a supplementary verification voltage, from among the plurality of memory cells that are programmed to the target state; and
applying a supplementary program voltage to the selected ones of the plurality of memory cells,
wherein the supplementary verification voltage is equal to or higher than the verification voltage and the supplementary program voltage is equal to or lower than a program voltage, provided in a program loop where programming of ones of the plurality of memory cells to the target state is completed, from among the incremental step pulses.

2. The method of claim 1, wherein programming the plurality of memory cells comprises generating pass loop count information associated with a program loop in which the programming of the plurality of memory cells to the target state is completed.

3. The method of claim 2, wherein a supplementary program voltage or a supplementary verification voltage corresponding to the target state is determined based on the pass loop count information.

4. The method of claim 1, wherein in programming the plurality of memory cells, data written at the plurality of memory cells are maintained at a page buffer without initialization.

5. The method of claim 1, wherein in programming the plurality of memory cells, data written at the plurality of memory cells are stored and maintained at a storage element that the nonvolatile memory device includes.

6. The method of claim 5, wherein in selecting ones of the plurality of memory cells, memory cells having the target state and threshold voltages lower than the supplementary verification voltage are selected based on data stored at the storage element.

7. The method of claim 1, further comprising:
selecting ones of the plurality of memory cells, each having a threshold voltage equal to or lower than the supplementary verification voltage, from among the plurality of memory cells programmed to the target state.

8. The method of claim 7, further comprising:
applying an additional supplementary program voltage to the ones of the plurality of memory cells that are selected, a level of the additional supplementary program voltage being different from a level of the supplementary program voltage.

9. The method of claim 8, wherein the additional supplementary program voltage is lower than the supplementary program voltage.

10. The method of claim 1, wherein each of the plurality of memory cells includes a charge trap layer.

11. The method of claim 1, wherein the non-volatile memory is monolithically formed in one or more physical levels of memory cells having active areas that are above a silicon substrate.

12-20. (canceled)

21. A method of programming a nonvolatile memory device, comprising:
performing a normal program operation in which a plurality of memory cells are programmed to a target state using incremental step pulses; and
performing a supplementary program operation in which selected memory cells, each having a threshold voltage lower than a supplementary verification voltage, from among the plurality of memory cells are selected and a supplementary program voltage is applied to the selected memory cells,
wherein the supplementary program voltage is higher than or equal to a verification voltage used at the normal program operation, and
wherein the supplementary program voltage is lower than or equal to a program voltage that is used in a program loop where the target state is program passed at the normal program operation.

22. The method of claim 21, wherein performing the normal program operation comprises generating loop count information corresponding to a pass loop of the target state.

23. The method of claim 22, further comprising determining levels of the supplementary verification voltage and the supplementary program voltages, based on the loop count information.

24. The method of claim 21, wherein performing the supplementary program operation is at least twice iterated with respect to the target state.

25. The method of claim 21, wherein the nonvolatile memory device comprises a three-dimensional memory array.

26. The method of claim 25, wherein the three-dimensional memory array comprises a non-volatile memory that is monolithically formed in one or more physical levels of memory cells having active areas that are above a silicon substrate.

27. The method of claim 25, wherein the three-dimensional memory array comprises a plurality of memory cells, and wherein each of the plurality of memory cells includes a charge trap layer.

28. A method of programming a nonvolatile memory device, comprising:
programming a plurality of memory cells to respective ones of a plurality of target states using verification voltages and incremental step pulses that correspond to the respective ones of the plurality of target states;
selecting ones of the plurality of memory cells that include threshold voltages that are lower than corresponding supplementary verification voltages, from among the plurality of memory cells that are programmed to the respective ones of the plurality of target states; and
applying supplementary program voltages to corresponding ones of the selected ones of the plurality of memory cells,
wherein the supplementary verification voltages are equal to or greater than the corresponding verification voltages and the supplementary program voltages are equal to or less than corresponding program voltages, provided in program loops where programming of ones of the plurality of memory cells to the respective ones of the plurality of target states is completed, from among the incremental step pulses.

29. The method of claim 28, wherein programming the plurality of memory cells comprises generating pass loop count information associated with a plurality of program loops that correspond to respective ones of the plurality of target states in which the programming of the plurality of memory cells to the plurality of target states is completed.

30-32. (canceled)
